(19) United States
(12) Patent Application Publication
(10) Pub. No.: US 2007/0298558 A1
(43) Pub. Date: Dec. 27, 2007

(54) METHOD OF FABRICATING SEMICONDUCTOR DEVICE AND SEMICONDUCTOR DEVICE

(75) Inventors: Takashi YAMAUCHI, Kanagawa (JP); Atsuhiro Kinoshita, Kanagawa (JP); Yoshinori Tsuchiya, Kanagawa (JP); Junji Koga, Kanagawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/738,687

(22) Filed: Apr. 23, 2007

(30) Foreign Application Priority Data
Jun. 22, 2006 (JP) 2006-173062

(51) Int. Cl. H01L 21/8234; H01L 21/336

(52) U.S. Cl. 438/197; 438/299; 438/305; 438/300

(57) ABSTRACT

A semiconductor device includes a first semiconductor region of first type conductivity with a channel region being formed therein, a gate electrode insulatively formed above the channel region, a layer of SiₓGe₁₋ₓ (0<x<1) on both sides of the channel region, a pair of second semiconductor regions of second type conductivity as formed on the SiₓGe₁₋ₓ layer to have a controlled impurity concentration ranging from 10²¹ to 10²² atoms/cm³, and a nickel-containing silicide layer above the second semiconductor regions. A fabrication method of the semiconductor device is also disclosed.

### CROSS-REFERENCE TO RELATED APPLICATION

This application is based on and claims priority of Japanese Patent Application (JPA) No. 2006-173062, filed Jun. 22, 2006, the disclosure of which is incorporated herein by reference.

### FIELD OF THE INVENTION

The present invention relates generally to semiconductor devices, and more particularly to a semiconductor device having a metal insulator semiconductor field effect transistor (MISFET) with improved source/drain (S/D) structure. This invention also relates to a method of fabricating the semiconductor device.

### BACKGROUND OF THE INVENTION

Silicon-based ultralarge-scale integrated (ULSI) circuit is one of key technologies that support highly advanced information-intensive societies in near future. For further advances in functionality of silicon ULSI devices, it is inevitable to enhance the performance of MISFETs for use as major circuit elements on ULSI chips. Until today, the device performance enhancement has been principally achieved based on proportional downsizing rules, called the “scaling.” However, in recent years, not only challenges to achieve higher performance by nanoscale miniaturization of on-chip devices but also chip designs for retaining operability of these devices per se are facing up to difficult circumstances. This is largely due to the presence of various limits in physical properties.

One of such physicality limits is a problem as to parasitic resistance components in source/drain (S/D) regions. See FIG. 64, which shows a typical transistor structure of prior known MISFET device. As shown herein, a silicide film 110 is formed at S/D electrode, with Schottky junction being formed between this silicide film 110 and a heavily-doped impurity region 107 surrounding silicide film 110 and its associated extension diffusion layer 105. The parasitic resistance of S/D electrode in this case is generally made up of three resistance components: the silicide film's own resistivity Rs, the impurity region's resistively Rd, and interface resistance Rc of the junction.

An approach to reducing the silicide film resistivity Rs is disclosed in P. Ranade et al., “High performance 35 nm L_{gate} CMOS Transistors Featuring NiSi Metal Gate (FUSI), Uniaxial Strained Silicon Channels and 1.2 nm Gate Oxide”, International Electron Devices Meeting (IEDM) 2005, Technical Digest, which teaches the use of a NiSi film that is lower in resistance than traditional films of TiSi₂ and CoSi₂. This NiSi film is an expecting material because of its advantages which follow: this material is superior in low temperature fabrication capability in addition to its low resistivity; the material is less in silicon (Si) consumption amount during silicide formation to enable fabrication of a shallow silicide layer; and, its work function is near a mid gap of Si band and thus offers simultaneous applicability as silicide material for FETs of both n-channel type and p-channel type.

As is well known, in order to reduce the junction interface resistance Rc, it is important that the impurity concentration is increased at an interface portion between the silicide film 110 and heavily-doped impurity layer 107.

FIG. 65 shows a band diagram of Schottky junction to be formed between the silicide film 110 and heavily-doped impurity region (Si film) 107. Electrons move or migrate between these films by tunneling a peak of energy equivalent to the height of Schottky barrier. This electron's tunneling activity is generally called the tunnel probability. The higher the tunnel probability of junction interface, the lower the interface resistance. It is also known that the tunnel probability decreases exponentially with respect to a product of Schottky barrier height and tunneling distance; thus, effectively reducing the Schottky barrier height and tunnel distance leads to a decrease in interface resistance. As shown in FIG. 66, heightening the impurity concentration at the interface of silicide film 110 and heavily-doped impurity region 107 permits creation of the effect for enhancing the curvature of Si layer's band, resulting in a likewise decrease in tunnel distance. Further, the Schottky barrier height per se is lowered, as apparent also from the band diagram of FIG. 66 with calculation of mirror image effects involved. Thus, the product of Schottky barrier height and tunnel distance decrease in value to achieve reduction of the interface resistance Rc.

One prior art NiSi layer-forming process is shown in FIG. 67. This process includes the steps of forming source/drain (S/D) diffusion regions in a semiconductor layer, depositing by sputtering a nickel (Ni) film on these regions, and then performing silicidation. With this process, however, it has been difficult to increase the impurity concentration at the interface between silicide film 110 and heavily-doped impurity region 107—in particular, in the case of p-type silicon (Si). Backside secondary ion mass spectrometry (SIMS) observation results of an interface of NiSi layer and heavily-doped impurity layer as formed by the process of FIG. 67 are shown in FIGS. 68A and 68B. As shown in FIG. 68A, in the case of arsenic (As) that is a representative impurity of n-type Si, the concentration distribution is seen on the both side of the interface. In contrast, in the case of boron (B) that is a typical impurity of p-type Si, its concentration is extremely low on the Si side as shown in FIG. 68B. This is because B impurity is accommodated into the NiSi film during silicidation so that most of it is distributed in NiSi film. As apparent from the foregoing, the prior art NiSi layer formation process is faced with a problem as to the difficulty in lowering the junction interface resistance Rc.

It is also known that the use of NiSi film for S/D electrodes can result in an unwanted increase in junction leakage current due to the fact that Ni atoms readily diffuse in silicon.

### SUMMARY OF THE INVENTION

The present invention was made in view of the above-noted background, and its object is to provide a semiconductor device having high-performance MISFETs with low resistance junction interface while reducing junction leakage and also a fabrication method of the semiconductor device.

To attain the foregoing object, a semiconductor device fabrication method (or manufacturing method or making method) in accordance with one aspect of this invention is arranged to include the steps of forming a gate electrode above a first semiconductor region of first type conductivity with a gate insulation film being interposed therebetween, forming a sidewall dielectric film on both side faces of the gate electrode, forming in or on the first semiconductor region a second semiconductor region of second type conductivity having an impurity concentration of more than or equal to 10²¹ atoms per cubic centimeter (atoms/cm³) and yet less than or equal to 10²² atoms/cm³, forming a silicon (Si) layer on the second semiconductor region, and causing the silicon layer to react with a nickel (Ni)-containing metal for silicidizing (siliciding) of the layer.

In accordance with another aspect of the invention, a semiconductor device fabrication method includes the steps of forming a gate electrode above a first semiconductor region of first type conductivity with a gate insulation film being interposed therebetween, forming a sidewall dielectric film on both side faces of the gate electrode, etching the first semiconductor region with the sidewall dielectric film being as a mask therefor, forming a layer of SiₓGe₁₋ₓ (0<x<1) in an etched region of the first semiconductor region, forming on the layer of SiₓGe₁₋ₓ (0<x<1) a second semiconductor region of second type conductivity having an impurity concentration of more than or equal to 10²¹ atoms/cm³ and yet less than or equal to 10²² atoms/cm³, forming a Si layer on the second semiconductor region, and causing the silicon layer to react with a Ni-containing metal for silicidation.

In accordance with still another aspect of the invention, a semiconductor device manufacturing method includes the steps of forming a gate electrode above a first semiconductor region of first type conductivity with a gate insulation film being interposed therebetween, forming a sidewall dielectric film on both side faces of the gate electrode, etching the first semiconductor region with the sidewall dielectric film being as a mask, forming a layer of SiₓGe₁₋ₓ (0<x<1) in an etched region of the first semiconductor region, forming on the layer of SiₓGe₁₋ₓ (0<x<1) a second semiconductor region of second type conductivity having an impurity concentration of more than or equal to 10²¹ atoms/cm³ and yet less than or equal to 10²² atoms/cm³, causing the gate electrode to react, for silicidation, with a Ni-containing metal to a level corresponding to an interface of the sidewall dielectric film, forming a Si layer on the second semiconductor region, and causing the silicon layer to react with a metal without containing nickel therein to thereby silicidize the silicon layer.

In accordance with yet another aspect of the invention, a semiconductor device fabricating method includes the steps of forming a gate electrode above a first semiconductor region of first type conductivity with a gate insulation film being interposed therebetween, forming a sidewall dielectric film on both side faces of the gate electrode, etching the first semiconductor region with the sidewall dielectric film being as a mask, forming a layer of SiₓGe₁₋ₓ (0<x<1) in an etched region of the first semiconductor region, forming on the layer of SiₓGe₁₋ₓ (0<x<1) a layer of silicon, forming on the silicon layer a second semiconductor region of second type conductivity having an impurity concentration of more than or equal to 10²¹ atoms/cm³ and yet less than or equal to 10²² atoms/cm³, causing the gate electrode to react with a Ni-containing metal to a level corresponding to an interface of the sidewall dielectric film to thereby silicidize the gate electrode, and causing the second semiconductor region and the silicon layer to react, for silicidation, with a metal which does not contain Ni therein.

In accordance with a further aspect of the invention, a semiconductor device includes a first semiconductor region of first type conductivity with a channel region being formed therein, a gate electrode overlying the channel region with a gate insulator film being sandwiched therebetween, a layer of SiₓGe₁₋ₓ (0<x<1) on both sides of the channel region, a second semiconductor region of second type conductivity as formed on or above the SiₓGe₁₋ₓ (0<x<1) layer to have an impurity concentration of more than or equal to 10²¹ atoms/cm³ and yet less than or equal to 10²² atoms/cm³, and a silicide layer containing Ni as formed above the second semiconductor region.

In accordance with another further aspect of the invention, a semiconductor device includes a semiconductive substrate and a pair of field effect transistors (FETs) having opposite conductivity types on the substrate. One of these FETs is of p-channel type whereas the other of them is of n-channel type. The p-channel type FET (pFET) includes a third semiconductor region of n-type conductivity with a first channel region being formed therein, a gate electrode overlying the first channel region with a gate insulator film being interposed therebetween, a layer of SiₓGe₁₋ₓ (0<x<1) on both sides of the first channel region, a fourth semiconductor region of p-type conductivity as formed on the SiₓGe₁₋ₓ (0<x<1) layer to have an impurity concentration of more than or equal to 10²¹ atoms/cm³ and yet less than or equal to 10²² atoms/cm³, and a first silicide layer containing Ni as formed above the fourth semiconductor region. The n-channel type FET or “nFET” includes a fifth semiconductor region of p-type conductivity with a second channel region being formed therein, a gate electrode overlying the second channel region with a gate insulator film being interposed therebetween, and a second silicide layer on both sides of the second channel region.

In accordance with the invention as disclosed herein, it becomes possible to provide a semiconductor device having high-performance MISFETs with low resistance junction interfaces while preventing or at least greatly suppressing the occurrence of junction leakage, and also provide a fabrication method of the semiconductor device.

### BRIEF DESCRIPTION OF THE DRAWINGS

FIG. 1 is a diagram showing a cross-sectional structure of main part of a semiconductor device in accordance with a first embodiment of this invention.

FIG. 2 is a diagram graphically showing the relationship of the concentration distribution of boron (B) in NiSi layer versus the height of Schottky barrier (Eᵥ−E_{F}=φB).

FIG. 3 depicts a sectional view of a modified example of the semiconductor device shown in FIG. 1.

FIGS. 4 through 13 illustrate, in cross-section, some major steps in the manufacture of the semiconductor device of FIG. 1.

FIG. 14 depicts a cross-sectional structure of main part of a semiconductor device in accordance with a second embodiment of this invention.

FIG. 15 shows a sectional structure of main part of a semiconductor device in accordance with a third embodiment of the invention.

FIGS. 16 to 23 illustrate, in cross-section, some major steps in the manufacture of the semiconductor device of FIG. 15.

FIG. 24 shows a cross-sectional structure of a semiconductor device in accordance with a fourth embodiment of the invention.

FIGS. 25 to 29 illustrate, in cross-section, major steps of a process for fabricating the semiconductor device shown in FIG. 24.

FIGS. 30 to 34 depict, in cross-section, major steps of another process of fabricating the device of FIG. 25.

FIG. 35 shows a cross-sectional structure of a semiconductor device in accordance with a fifth embodiment of the invention.

FIGS. 36 to 39 illustrate, in cross-section, some major steps in the manufacture of the semiconductor device shown in FIG. 35.

FIG. 40 shows a cross-sectional structure of a semiconductor device in accordance with a sixth embodiment of the invention.

FIGS. 41 to 50 illustrate, in cross-section, some major steps in the manufacture of the device shown in FIG. 40.

FIG. 51 shows a cross-sectional structure of main part of a semiconductor device in accordance with a seventh embodiment of the invention.

FIGS. 52-56 illustrate, in cross-section, major steps in the manufacture of the device shown in FIG. 51.

FIG. 57 shows a cross-sectional structure of main part of a semiconductor device in accordance with an eighth embodiment of the invention.

FIGS. 58-63 depict, in cross-section, major steps in the manufacture of the device shown in FIG. 57.

FIG. 64 shows a typical structure of prior known MISFET device.

FIG. 65 is an energy band diagram of Schottky junction between a silicide film and a heavily-doped impurity region of a silicon (Si) film.

FIG. 66 is a graph showing plots of energy for explanation of interface resistance-reducing effect.

FIG. 67 is a diagram showing the flow of a prior art NiSi film forming process along with the indication of some impurity distribution states.

FIGS. 68A-68B are graphs each showing a distribution of doped impurity concentration in the prior art NiSi film formation process.

### DETAILED DESCRIPTION OF THE INVENTION

It was found by the inventors as named herein that a semiconductive layer having its impurity concentration of 10²¹ atoms per cubic centimeter (/cm³) or higher exhibits its superior operability to function as a barrier against the diffusion of nickel (Ni) atoms. A principal feature of this invention lies in applying a heavily-doped impurity region acting as this Ni diffusion barrier to semiconductor devices and fabrication method thereof.

An explanation will first be given of the principle of such Ni diffusion barrier property or “barrierability” of this heavily-doped impurity region.

To examine the Ni diffusion barrierability of heavily-doped impurity regions, an attempt was made to calculate an energy gain (i.e., generation energy) as obtained when a Ni or B atom makes a transit from a vacuum to an inter-lattice position in Si or a Si substitution position. A method for such calculation uses, upon exceeding of local-density function proximity, a technique of spin-polarized generalized gradient approximation (SP-GGA) with spin polarization being also considered. The calculation was executed for a unit lattice which contains sixty four (64) Si atoms. The calculation assumes that one side of the lattice is 1.086 nanometers (nm). In case an impurity of Ni or B resides in the unit lattice of Si, the generation energy, E_{f}, is defined by the equation which follows.

If an impurity atom is at the interlattice position, E_{f}^{Int}=−Eₐ+E_{b}+E_{c}, where Eₐ is the energy of a cell structure consisting of 64 Si atoms with a single impurity contained therein, E_{b} is the energy of a cell structure of 64 Si atoms, and E_{c} is that of the single impurity in the vacuum. Alternatively, if an impurity atom is at Si-exchange position, E_{f}^{Si}=Eₚ−E_{q}+E_{b}+E_{c}, where Eₚ is the energy of a cell structure consisting of 63 Si atoms with a single impurity involved therein, and E_{q} is that of a Si atom in a balk. It should be noted that in case the impurity atom enters the Si exchange position, the computation was done under an assumption that a Si atom exited from a lattice point behaves to return to the balk's Si layer. Calculation results as to the generation energy are given below in Table 1.

TABLE 1

| | Interlattice | Si Exchange |
|---|---|---|
| | Position (eV) | Position (eV) |
| B | 2.61 | 5.19 |
| Ni | 4.10 | 3.62 |

Generally, it is considered that real systems experience easy establishment of a state that the generation energy becomes greater. Thus, from the calculation results of the table above, it is very likely that a B atom enters the Si exchange position in Si whereas Ni atom enters the interlattice position. In case the both atoms reside in Si, it is expected that B atom enters Si exchange position while Ni atom enters interlattice position. However, in an event that B impurity concentration becomes noticeably higher to go beyond a prespecified concentration level such as in heavily B-doped source/drain (S/D) regions of MISFET on Si substrate, B atoms are such that some of them reside at Si exchange positions and simultaneously an appreciable amount of remaining B atoms are at interlattice positions. It is also predicted that in the case of such Ni atoms being diffused into the heavily B-doped S/D regions, Ni atoms are incapable of residing not only at Si exchange positions but also at interlattice positions. This results in that a heavily-doped region with an increased amount of impurity residing at interlattice positions has the barrier functionality—i.e., it functions as a barrier against diffusion of Ni atoms.

The concentration of a single B atom contained in a unit lattice is equivalent to the impurity concentration of 7.8×10²⁰ atoms/cm³. Accordingly, it is believed that setting the B concentration at 10²¹ atoms/cm³ or greater serves to increase the probability that the interlattice positions are occupied by B atoms, resulting in the diffusion barrierability against Ni atoms becoming noticeable. The upper limit of such B concentration value is 10²² atoms/cm³. This can be said because it is hardly occurrable that the B impurity becomes higher in concentration than Si atoms in Si crystal.

The unit lattice is 1.086 nm in its one side length. In the light of randomness of B position in the unit lattice, the Ni diffusion barrierability is expected to become more noticeable relative to certain films having a thickness of less than or equal to 2 nm, which is about twice is the lattice side length. Note here that the thinner the heavily-doped impurity regions, the less the number of stable cites at the interlattice position whereat diffused Ni atoms reside; thus, it becomes possible to more effectively suppress the diffusion of Ni atoms. In reality, a lower limit of the thickness of such impurity regions is 0.55 nm since it is impractical to make these regions thinner than the lattice constant (=0.543 nm) of Si single-crystal.

Although in Table 1 the calculation results in the case where B and Ni atoms are involved in Si unit lattice for demonstration of the effects as derived therefrom, it is readily presumable that similar results are obtainable in a silicon germanium (SiGe) unit lattice which resembles thereto in crystal structure. Also note that similar Ni diffusion barrierability is achievable not only for B atoms as used to form p-type impurity regions but also for arsenic (As) for creation of n-type impurity regions together with carbon (C) at a mixture ratio of 1:1 to obtain an impurity concentration of 10²¹ atoms/cm³ or higher, wherein an As atom resides at Si exchange positions whereas C atom is at Si interlattice position. For other kinds of impurities such as phosphorus (P), antimony (Sb) or bismuth (Bi), similar effects are expected theoretically.

### First Embodiment

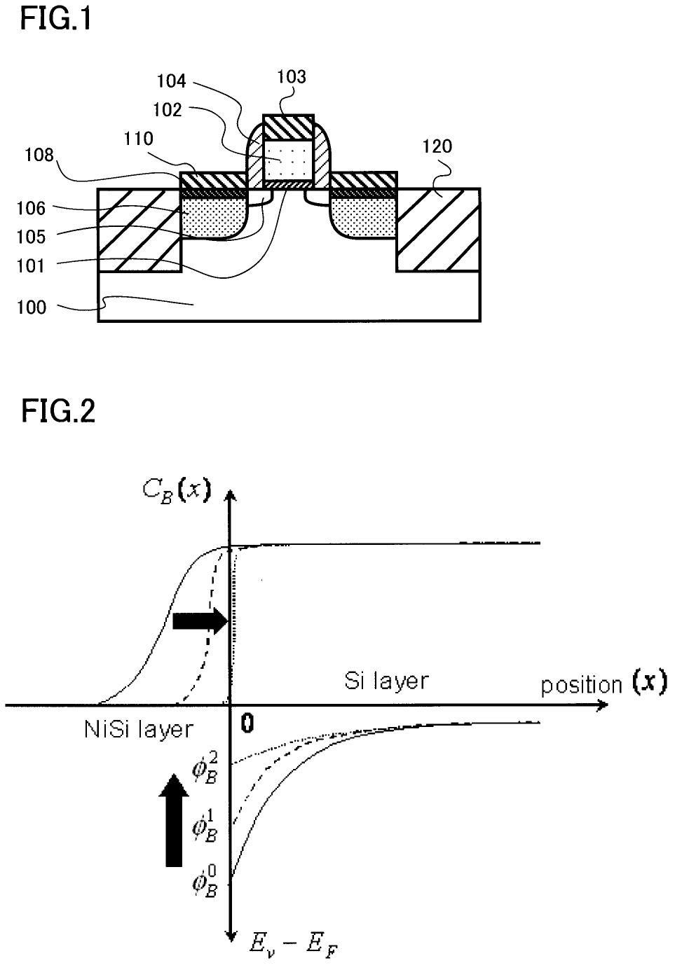

A semiconductor device having a metal insulator semiconductor field effect transistor (MISFET) in accordance with an embodiment of this invention is depicted in cross-section in FIG. 1. The MISFET is illustratively a p-conductivity type MISFET (pMISFET), which has a pair of laterally spaced-apart portions of a SiGe layer on the both sides of a channel region and a nickel silicide (NiSi) layer that is formed above SiGe layer with a heavily-doped impurity region interposed therebetween. In the description, the term first conductivity type refers to either one of n-type and p-type whereas the term second conductivity type is the other of them. The first and second conductivity types are different from each other.

More specifically, a silicon (Si) substrate (first semiconductor region as claimed) 100 of n-type conductivity has a top surface of a (100) surface orientation, which is doped with a chosen impurity, e.g., phosphorus (P), to a concentration of about 10¹⁵ atoms/cm³. In this Si substrate 100, a pair of spaced shallow trench isolation (STI) regions 120 made of Si oxide are formed. A gate electrode structure is formed above Si substrate 100 with a gate insulating film 101 sandwiched therebetween. This gate structure has a polycrystalline silicon or “polysilicon” gate electrode 102 and a gate silicide film 103 formed thereon.

The gate electrode structure of two stacked layers 102-103 has opposite side surfaces, on which gate sidewall insulator films 104 are formed. A channel region is defined in Si substrate 100 at a surface portion underlying the gate electrode 102, on the opposite sides of which channel region are formed a couple of p-type extension diffusion layers 105 and a pair of SiGe layers 106 connected thereto respectively. Each SiGe layer 106 has its surface in which p-type heavily-doped impurity region (second semiconductor region as claimed) 108 is formed. This region 108 contains boron (B) as an impurity in Si or SiGe, which impurity is doped to a concentration of 10²¹ atoms/cm³ or greater—preferably, 10²² atoms/cm³. On the heavily-doped p-type or “p⁺”-type impurity region 108 is formed a silicide layer 101 made of nickel silicide (NiSi) which is for use as a source/drain (S/D) electrode. The formation of such SiGe layer 106 is to give crystal lattice distortion to the channel silicon by burying SiGe layer in S/D region in order to improve the mobility of electrical charge carriers.

In the MISFET device shown in FIG. 1, the NiSi silicide layer 110 has an interface with its impurity concentration of 10²¹ atoms/cm³ or more. Thus the product of Schottky barrier height and tunnel distance is sufficiently reduced in value to thereby achieve successful reduction of the interface resistance.

Also note that the p⁺-type impurity region (second semiconductor region) 108 underlying the NiSi silicide layer 110 functions as the diffusion barrier of Ni atoms as stated previously. Accordingly, unwanted increase in junction leakage is effectively suppressed, which occurs due to the diffusion of Ni atoms that constitute silicide layer 110 toward the Si substrate 100 side.

The p⁺-type impurity region 108's functionality as the Ni atom diffusion barrier also avoids a problem as to an increase in the junction interface resistance Rc otherwise occurring due to formation of a NiSiGe high-resistance layer through reaction of the NiSi silicide layer 100-constituting Ni atoms with SiGe in either the underlying SiGe layer or the p⁺-type impurity region 108. This in turn serves to prevent occurrence of a parasitic resistance increase occurrable due to an increase in interface resistance of NiSi silicide layer 110. Thus, it becomes possible to increase the mobility of channel distortion owing to the SiGe layer without suffering from the risk of a parasitic resistance increase.

In this way, according to the illustrative embodiment, it is possible to provide the intended semiconductor device having high-performance pMISFET with increased drivability owing to the junction interface resistance reduction and carrier mobility increase effects while at the same time offering high speed performance and low power consumption with the junction leakage restrained.

Preferably the p⁺-type impurity region 108 is arranged to have its thickness of more than or equal to 0.55 nm and yet less than or equal to 2 nm. One reason of this thickness setting is as follows: as stated supra, in view of the random positioning of B atoms in unit lattice, if the thickness is not greater than 2 nm equivalent to the twice the length of one side of unit lattice, then the Ni diffusion barrier effect becomes more noticeable. Another reason is that it is impractical to thin the impurity region to less than the lattice constant (=0.543 nm) of Si single-crystals.

Regarding the B impurity concentration in NiSi layer, this is desirably set at 10¹⁸ atoms/cm³ or below. This can be said because lowering the B concentration in NiSi layer permits the Schottky barrier height to decrease, resulting in a decrease in interface resistance of NiSi and Si layers. See FIG. 2, which graphically shows the relationship of concentration distribution of boron (B) in NiSi layer and Schottky barrier height (Eᵥ=E_{F}=φB). In the upper side of this graph, B concentration distributions of NiSi and Si layers are plotted; on its lower side, curves of Schottky barrier height in respective distributions are indicated.

In general, it is known that the Schottky barrier height relative to holes in the case of B being not doped is at about 0.45 electron-volts (eV). In the presence of B in NiSi side, the Schottky barrier drops down to about 0.3 eV. This is due to the so-called Schottky barrier height modulation effect. Specifically, in case NiSi/Si interface is formed, Si atoms in one or two layers on the Si layer side experience creation of a large number of dangling bonds so that B atoms become more stable by replacement of such Si atoms. This B atom replacement causes the interface's Fermi level to shift toward the end of valance band due to production of dipoles at the interface, resulting in the Schottky barrier height being greatly lowered as indicated by dotted line in FIG. 2. Thus, the interface resistance also decreases. However, in case B impurity distributes in the both layers with the interface interposed therebetween, charge migration effects are cancelled out each other, resulting in diminishment of the Schottky barrier height reduction effect as shown by solid line in FIG. 2.

Additionally, prior art NiSi film fabrication methods have difficulties in sufficiently obtaining the above-noted Schottky barrier height reduction effect because of the fact that B impurity is accommodated into silicides during NiSi formation resulting in B being widely distributed on the NiSi side also as indicated by solid line at upper part of FIG. 2. In contrast, with a manufacturing method embodying this invention to be later described, it becomes possible to retain lower the B impurity concentration in NiSi layer.

Also preferably, the NiSi layer contains therein about 10% of platinum (Pt). One reason is that this Pt containment lowers the electrical resistance of S/D silicide layers, resulting in improvement of MISFET drivability. Another reason is that the silicide layer's interface with the substrate side is planarized at the level of atoms, thereby enabling suppression of junction leakage between S/D and substrate otherwise occurring due to the presence of silicides.

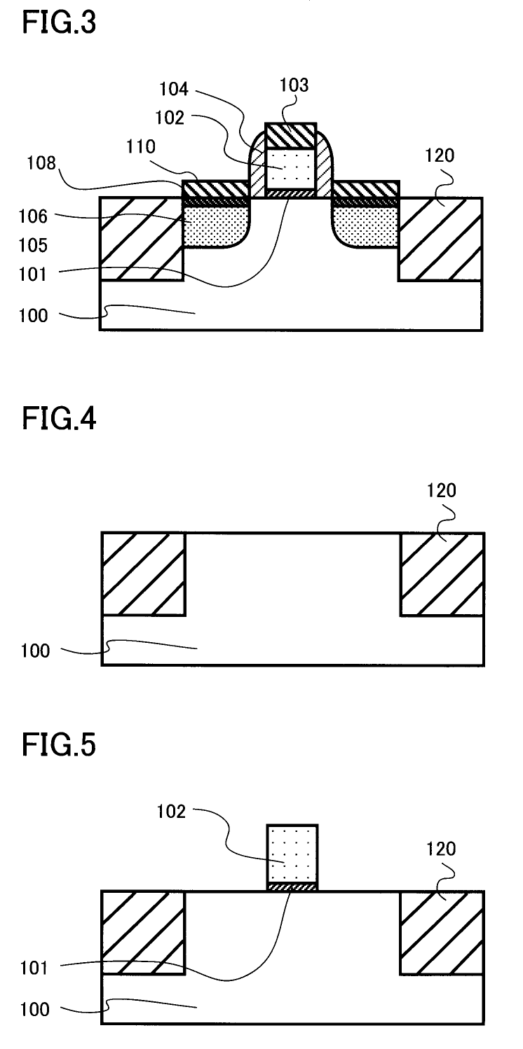

In the MISFET device structure of FIG. 1, the extension diffusion layers 105 may be omitted when the need arises. An exemplary structure using this approach is shown in FIG. 3, which is without the extension diffusions. This is called the Schottky source/drain p-type FET structure. With such the structure, it is possible to suppress short-channel effects while at the same time attaining the functionalities and advantages of the device shown in FIG. 1.

A method for manufacturing the FET device also embodying the invention will be described with reference to FIGS. 4 through 13 below.

Firstly, as shown in FIG. 4, a Si substrate (first semiconductor region) 100 of n-type conductivity is prepared, which has a top surface with a (100) plane as doped with phosphorus (P) impurity to a concentration of about 10¹⁵ atoms/cm³. Then, form STI element isolation regions 120 made of silicon oxide in selected surface portions. Thereafter, form a gate insulating film 101 to have its equivalent oxide thickness (EOT) of about 1 nm, followed by low pressure chemical vapor deposition (LPCVD) of a poly-silicon film to a thickness of 100 to 150 nm. This film is for later use as the gate electrode 102 of FIG. 1.

Next, as shown in FIG. 5, use etching techniques such as lithography and reactive ion etch (RIE) processes to form a pattern of gate insulator film 101 and gate electrode 102 so that the gate length is about 30 nm. Post-oxidation may be done to a depth of 1 to 2 nm if necessary.

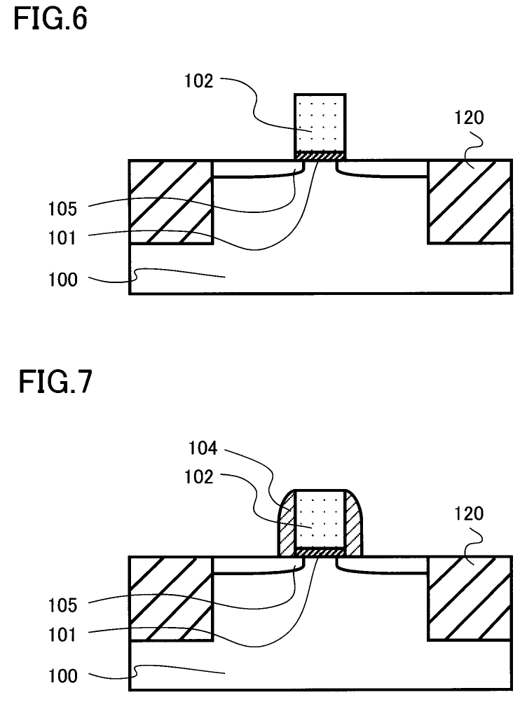

Then as shown in FIG. 6, selectively implant ions into Si substrate 100 to form extension diffusion layers 105, which are doped with boron (B) to a concentration of about 10²⁰ atoms/cm³, followed by activation annealing, also known as spike anneal, at a temperature of about 1,050° C.

Next as shown in FIG. 7, deposit a silicon nitride (SiN) film by LPCVD to a thickness of about 8 nm. Thereafter, perform etch-back by RIE techniques to thereby cause only selected portions of the SiN film to reside on sidewalls of gate electrode 102. Thus the gate sidewall insulator films 104 are formed.

Although single-layered SiN sidewalls are used here, these are replaceable by multilayered sidewall insulators each having the lamination of a tetra-ethyl-ortho-silicate (TEOS) oxide film with a thickness of about 3 nm and a 5 nm thick SiN film. With such multilayer structure, carrier trap to the lower surfaces of sidewall insulators is suppressed, thereby improving the reliability.

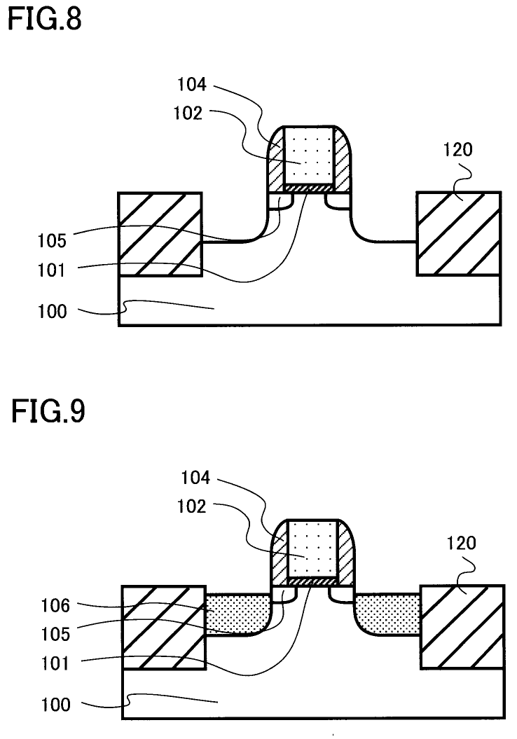

Next as shown in FIG. 8, etch and “dig” by about 30 nm the extension diffusion layers 105 and Si substrate 100 with the gate electrode 102 and sidewall insulators 104 being as a block mask therefor. At this time, in order to avoid unwanted etching of polysilicon gate electrode 102, a mask material may additionally be provided on gate electrode 102.

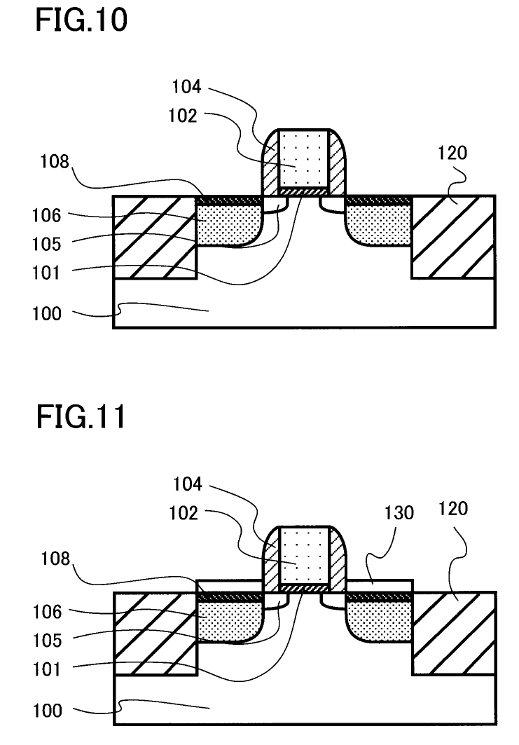

Then as shown in FIG. 9, selectively grow a SiGe epitaxial film 106 relative to the substrate-side crystal layer to fill the etched recesses in the substrate surface. Subsequently as shown in FIG. 10, add a raw gas of B to continue the selective epitaxial layer growth, thereby to form on each SiGe layer a p⁺-type impurity region (second semiconductor region) with a concentration of 10²¹ atoms/cm³ or more to a thickness of about 1.5 nm. Then, as shown in FIG. 11, change the raw gas to form a pattern of Si layer 130 by selective epitaxial growth techniques.

Note here that although in view of process simplification it is desirable to continuously form by selective epitaxial growth the SiGe layer 106, p⁺-type impurity regions 108 and Si layers 130, it may alternatively be possible to form the p⁺-type regions by B ion implantation.

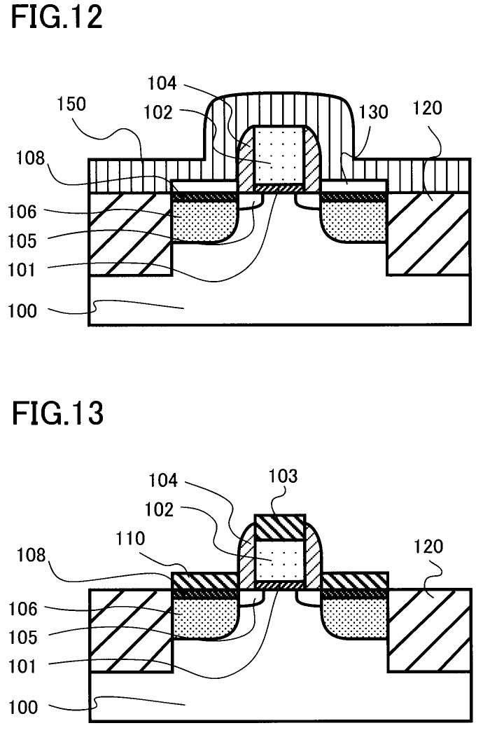

Next, as shown in FIG. 12, form by sputtering a Ni film 150 on the top surface of resultant structure to a thickness of about 10 nm. Then, perform annealing at 400° C. for 30 seconds with the aid of a chosen chemical liquid to remove or strip selected portions (non reacted portions) of Ni film 150. During the annealing, Ni film 150 and Si layer 130 plus polysilicon gate electrode 102 chemically react together, thereby forming a couple of laterally spaced-apart NiSi layer portions 110 for later use as S/D electrodes and a gate silicide 103 as shown in FIG. 13.

With this fabrication method, the heavily-doped impurity regions 108 act as the barrier against unwanted Ni diffusion whereby B is hardly accommodated into NiSi layer unlike prior art NiSi layer forming methods so that it is possible to retain B impurity concentration at a higher level at the substrate-side interface of NiSi layer. Thus it becomes possible to reduce or minimize the electrical resistance of the substrate-side interface of NiSi layer.

The feature of preventing B impurity from being taken into NiSi layer makes it possible to avoid unwanted suppression of Schottky barrier height reduction due to the B distribution in NiSi layer stated supra. Thus, in this viewpoint also, it is possible to reduce the electrical resistance of the NiSi layer's substrate-side interface.

Another advantage attainable by this embodiment is as follows. Since the p⁺-type impurity regions 108 serve as the Ni diffusion barrier, it becomes possible to lessen junction leakage otherwise occurring due to the diffusion of Ni atoms into the extension diffusion layers 105 and Si substrate 100.

In addition, the Ni diffusion barrierability of the p⁺-type impurity regions 108 prevents creation of a high-resistivity NiSiGe layer otherwise occurrable due to reaction of Ni atoms with the SiGe layer as used for improvement of the drivability of p-type FET (pFET). This in turn ensures that the FET's parasitic resistance no longer increases even in combined use of SiGe layer and NiSi layer, wherein the former is preferable for use as the fill layer that gives distortion to the channel whereas the latter is suitable for use as the S/D electrodes.

As apparent from the foregoing description, with the fabrication method incorporating the principles of this invention, it is possible to manufacture the semiconductor device having a junction leakage-suppressed high-performance pMISFET while achieving enhanced drivability owing to the resistance-reduced junction interface and the carrier mobility increasing effect.

Additionally the SiGe layer is not always arranged so that Si and Ge are of one-to-one composition ratio and may alternatively be designed so that these elements are in any given composition ratios: in other words, any available SiGe layers as expressed by SiₓGe₁₋ₓ (where 0<x<1) are employable in this embodiment.

Regarding the S/D silicide layers, these are not limited to the NiSi layers as in the illustrative embodiment. Similar effects and advantages are obtainable by replacement with Ni-containing silicide layers.

The above-stated advantages as derived from the Ni atom barrierability are also attainable not only for the illustrated pFET but also for nFET. In the case of the nEFT, it is preferable to use As and C as the impurity for the heavily-doped regions due to the reasons described above.

The impurity combination of B or As and C to be introduced into the heavily-doped regions is not to be construed as limiting the invention, and P, Sb or Bi impurity are alternatively employable when the need arises. Obviously, the semiconductor material of the heavily-doped regions should not be limited only to Si and SiGe and may be replaced by other materials such as GaAs, InP or else.

### Second Embodiment

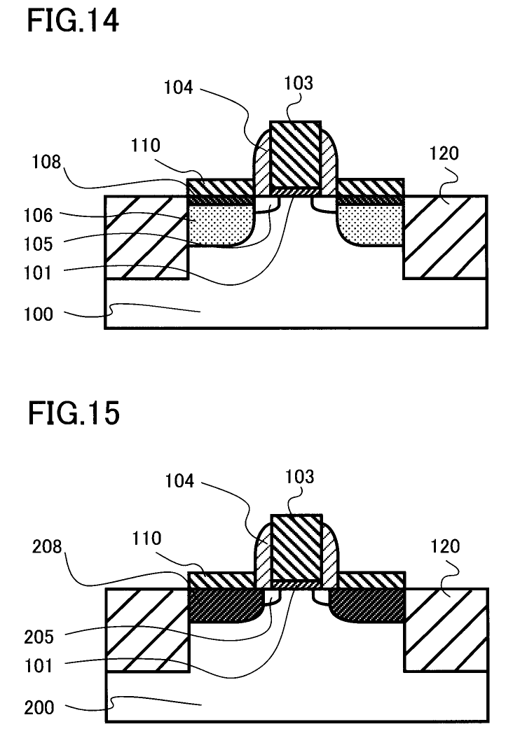

A semiconductor device structure having a MISFET in accordance with another embodiment of this invention is shown in FIG. 14 in cross-section. This device is similar to the pFET shown in FIG. 1 except that the former has a fully silicided (FUSI) structure with its gate electrode being formed of NiSi gate silicide layer 103 only.

This semiconductor device of FIG. 2 offers the functionality and advantages stated previously and also is capable of suppressing depletion on the gate electrode side during transistor driving within an extended range up to a higher gate voltage owing to the use of FUSI structure to thereby enable achievement of enhanced transistor drivability.

A fabrication method of the FIG. 14 device is similar to the method shown in FIGS. 4 to 13 except that the step of FIG. 12 for sputtering the Ni film 150 and performing silicidation by annealing is modified to perform the annealing for an increased length of time period until the polysilicon gate electrode 102 is completely silicided.

With prior known silicidation techniques, it has been difficult when silicidizing (siliciding) both the gate electrode's polysilicon and Si substrate at a time to differ the gate silicide and S/D electrode silicide from each other in film thickness. Consequently, FUSI structure fabrication would result in the S/D electrode silicide becoming thicker unintentionally, which leads to occurrence of punch-through between source and drain and leakage current increase due to junction penetration.

To avoid this problem, a need is felt to force the gate silicide and S/D electrode silicide to be different in film thickness from each other, which in turn requires use of a complicated fabrication method having extra processes for forming them independently of each other.

According the fabrication method of the device shown in FIG. 14, the film thickness of NiSi silicide layer 110 for use as S/D electrode is limited by the selective epitaxial grown Si film 130 (FIG. 12) because the silicidation reaction is suppressed by formation of heavily B-doped impurity regions 108 functioning as the Ni diffusion barrier beneath the NiSi layer 110. Accordingly, even when performing thermal processing for complete silicidation of the polysilicon gate electrode 102 (FIG. 12), the NiSi layer for use as S/D electrodes no longer exhibits further growth once after its film thickness reaches a prespecified level. Thus it becomes possible to readily perform at a process step both the complete gate electrode silicidation and the formation of NiSi S/D electrode film different in thickness from the gate silicide.

### Third Embodiment

A semiconductor device having a MISFET to be formed by a fabrication method in accordance with still another embodiment of the invention is shown in FIG. 15 in cross-section. This device has an nFET of FUSI structure with its gate electrode being made up of only a silicide monolayer 103 made of NiSi and a pair of NiSi S/D electrodes 110. The device also has at selected substrate surface portions a couple of heavily-doped n (n⁺) type impurity regions 208, each being doped with As and C impurities to a concentration of 10²¹ atoms/cm³ or greater but less than or equal to 10²² atoms/cm³. The presence of these n⁺-type S/D regions 208 is a unique structural feature of this embodiment.

A feature of this nFET lies in that the NiSi layer is high in impurity concentration at its substrate interface due to the presence of the n⁺-type S/D regions 208 so that the interface resistance is low. Another feature is that n⁺-type regions 208 serve as the barrier against unwanted diffusion of Ni atoms whereby junction leakage hardly occurs due to Ni diffusion. Furthermore, use of the FUSI structure makes it possible to suppress depletion on the gate electrode side when driving the transistor within an extended range up to a higher gate voltage, thereby enabling achievement of enhanced transistor drivability.

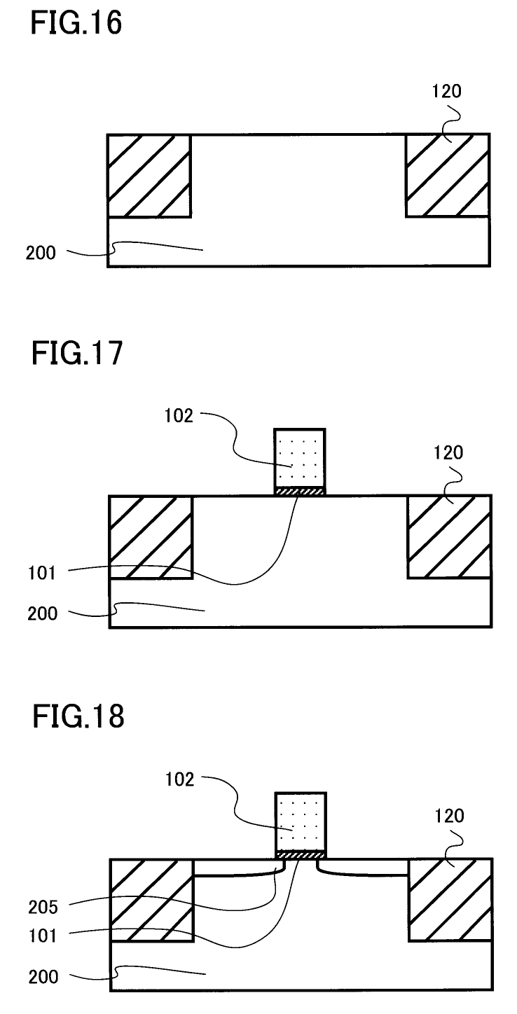

A fabrication method of the FIG. 15 device will be described with reference to FIGS. 16 to 23 below.

First, as shown in FIG. 16, a p-type Si substrate (first semiconductor region as claimed) 200 is prepared, which has a (100) plane with boron (B) being doped to a concentration of about 10¹⁵ atoms/cm³. Then, form shallow trench-like grooves for element isolation as filled with a silicon oxide film—i.e., STI regions 120. Thereafter, form a gate insulator film 101 to a thickness of about 1 nm while letting it be EOT, followed by deposition of a polysilicon film for use as gate electrode 102 by LPCVD techniques to a thickness of about 100 to 150 nm.

Next, as shown in FIG. 17, selectively etch for patterning the gate insulator film 101 and gate electrode 102 by lithography and RIE techniques in a way such that resultant gate length is 30 nm, or more or less. Here, post-oxidation may be done when the need arises.

Next as shown in FIG. 18, perform ion implantation to form n-type extension diffusion layers 205 as doped with As impurity to a concentration of about 10²⁰ atoms/cm³. Then, apply annealing for activation, known as the spike anneal, at a temperature of about 1050° C.

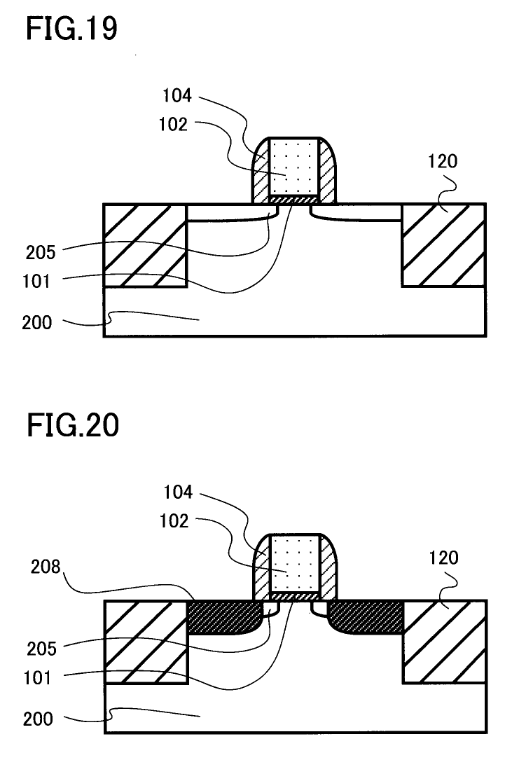

Next, as shown in FIG. 19, after having deposited a SiN film by LPCVD to a thickness of about 8 nm, perform RIE etch-back, causing only selected portions of SiN film to reside at sidewalls of gate electrode 102. Thus, gate sidewall insulator films 104 are formed.

Next as shown in FIG. 20, with the patterned gate electrode 102 and sidewall insulators 104 being as a mask, introduce by ion implantation As and C impurities into the Si substrate (first semiconductor region) 200 at a mixture ratio of 1:1 to thereby form n⁺-type impurity regions (second semiconductor regions) 208 with its concentration of 10²¹ atoms/cm³ to a thickness of about 1.5 nm. Then, apply activation annealing, called the spike anneal, at a temperature of about 1050° C. Thereafter, as shown in FIG. 21, form a Si layer 130 by selective epitaxial growth.

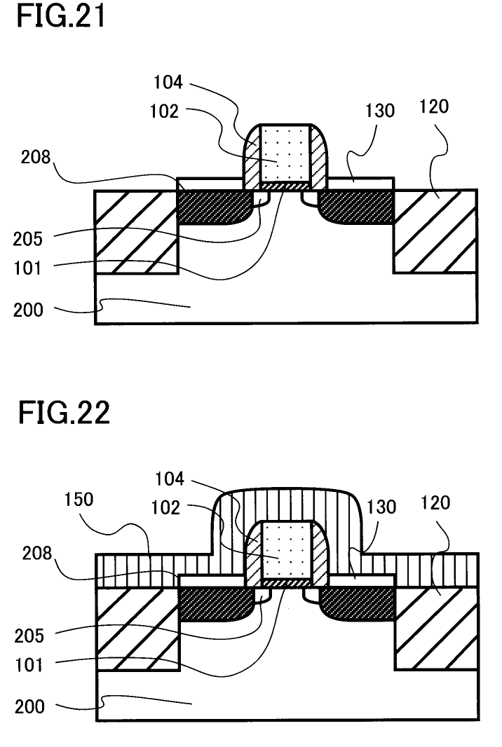

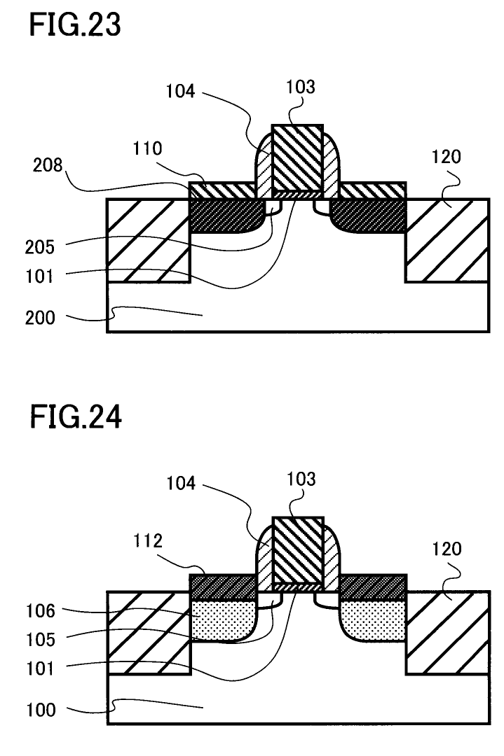

Next as shown in FIG. 22, perform sputtering to form a Ni film 150 of about 10 nm-thick and thereafter perform annealing at 400° C. for 90 seconds and then selective exfoliation or strip using a chosen chemical solution, thereby to force Ni film 150 and Si layer 130 to react together for silicidation as shown in FIG. 23. Simultaneously, allow poly-Si gate electrode 102 to undergo complete reaction to a point corresponding to the interface of gate insulator 101, thereby forming a gate silicide 103.

In accordance with the transistor fabrication method also embodying the invention, the thickness of NiSi silicide layer 110 for use as S/D electrodes is limited by the selectively epitaxial grown Si film 130 (FIG. 21) because of the fact that its reaction is suppressed by the formation of As/C high-impurity regions (second semiconductor regions) acting as the Ni diffusion barrier beneath NiSi layer 110. Accordingly, even when performing thermal processing for full silicidation of the polysilicon gate electrode 102 (FIG. 21), the NiSi layer for use as S/D electrodes no longer exhibits further growth once after its film thickness reaches a prespecified level. Thus it becomes possible to readily perform at a process step both the complete gate electrode silicidation and the formation of NiSi S/D electrode film 101 different in thickness from the gate silicide. Thus it is possible to fabricate the high-performance nFET with enhanced drivability owing to both parasitic resistance reduction and gate electrode depletion suppression while at the same time lowering the junction leakage thereof.

Although in this embodiment the poly-Si gate electrode 102 is fully reacted down to the interface of gate insulator film 101 to thereby form gate silicide 103, the poly-Si gate electrode may alternatively be processed so that it partially resides. Even with this fabrication method also, the transistor structure with the gate electrode resistance lowing effect is obtainable. Thus this invention should not be interpreted to exclude such approach.

While this embodiment is drawn to the nFET, similar effects and advantages are also attainable by replacing it by a pFET.

### Fourth Embodiment

A semiconductor device having a MISFET to be formed by a fabrication method in accordance with a further embodiment of this invention is shown in FIG. 24 in cross-section. This device is similar in structure to that of FIG. 14 with the silicide regions for use as S/D electrodes of pFET being replaced with platinum silicide (PtSi) layers 112 and with the heavily B-doped impurity regions (second semiconductor regions) being silicided.

The pFET thus structured is capable, in addition to the gate electrode depletion reducibility, of achieving further lowered parasitic resistance owing to the use of PtSi of lower resistance than NiSi as S/D electrodes, thereby enabling realization of further enhanced drivability. In addition, as the work function of PtSi is closer than NiSi to the energy of the valence band of Si, the silicide/substrate Schottky barrier becomes lower than NiSi. From this viewpoint also, the interface resistance is reduced, causing the parasitic resistance to decrease to thereby enable achievement of higher drivability. Furthermore, the PtSi layer's silicide interface becomes flat at the level of atoms. This permits the FET to become lower in power consumption owing to the junction leakage reduction effect.

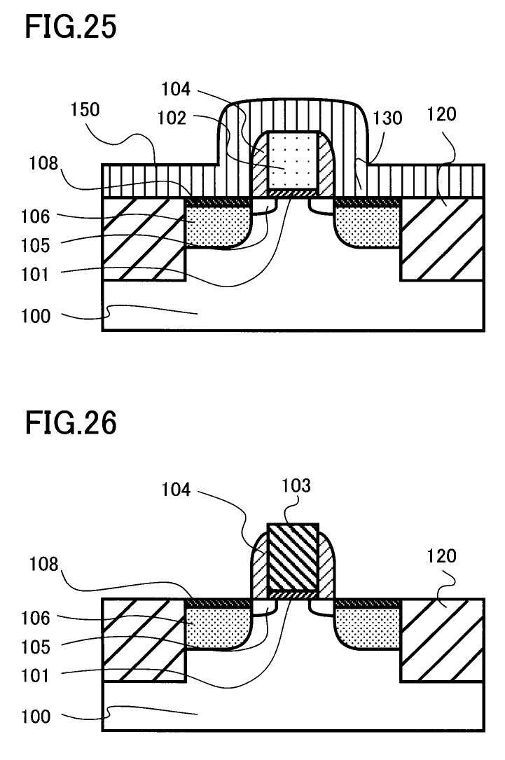

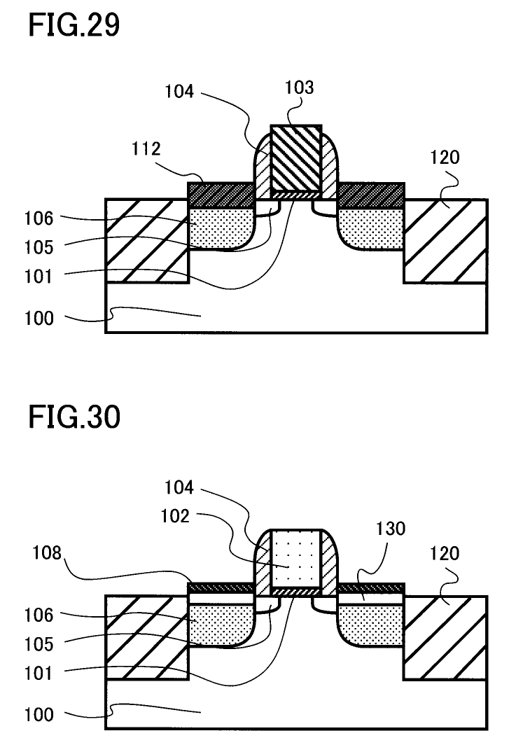

A first exemplary fabrication method of the transistor device of FIG. 24 will be described with reference to FIGS. 25 to 29 below. Note that its process up to the step of forming on SiGe layer 106 heavily B-doped impurity regions 108 is similar to that of Embodiment 1 (FIGS. 4-10), so its explanation will be eliminated herein.

After having formed by selective epitaxial growth the heavily B-doped p-type impurity regions 108 on SiGe layer, form by sputtering a Ni film 150 to a thickness of about 10 nm. Thereafter, as shown in FIG. 25, perform anneal at 400° C. for 90 seconds and selective strip using a chosen chemical liquid to thereby cause Ni film 150 and polysilicon gate electrode 102 to completely react together to a level corresponding to the interface of gate insulator film 101 as shown in FIG. 26, thus forming a gate silicide 103. At this time, those portions of Ni film overlying p⁺-type impurity regions 108 hardly react with these regions 108 due to the Ni diffusion barrierability thereof. Thus no NiSi layer is formed on p⁺-impurity regions 108.

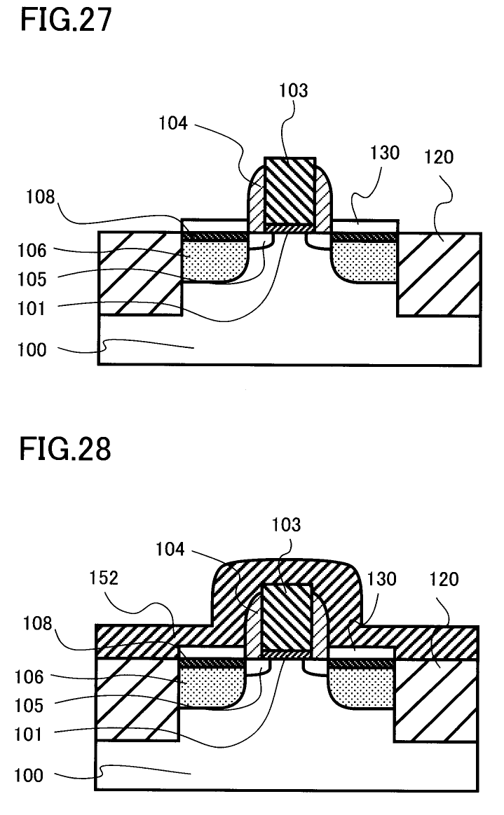

Then, as shown in FIG. 27, form by selective epitaxial growth a Si layer 130 on the p⁺-type B impurity regions (second semiconductor regions) 108. Next, as shown in FIG. 28, after having performed the sputtering of a Pt film 152 of about 10 nm thick, perform silicidation thereof by annealing at about 350° C. and then selective chemical strip, thereby to form a pFET with its S/D electrodes made of PtSi layer 112. At this time the p⁺-type impurity regions 108 are not expected to function as the diffusion barrier for Pt atoms. Thus, these regions 108 are silicidable partly or entirely.

Traditionally, in order to make the gate silicide and the S/D electrodes different in silicide material from each other, it has been required in such silicidation to add much complicated processes for masking those regions that are not desired to be silicided.

With use of the semiconductor device fabrication method shown in FIGS. 25-29, it becomes easier to allow the gate silicide and S/D electrode to be different in silicide materials from each other. This in turn makes it possible to facilitate reduction of the parasitic resistance of S/D regions of pFET while at the same time lowering the threshold voltage of pFET and nFET.

An explanation will next be given of a second example of the semiconductor device fabrication method of this embodiment while referring to FIGS. 30-34 below. Note that its process up to the step of forming SiGe layers 106 by selective epitaxial growth is similar to that of Embodiment 1 (FIGS. 4-9), so the description thereof will be omitted herein.

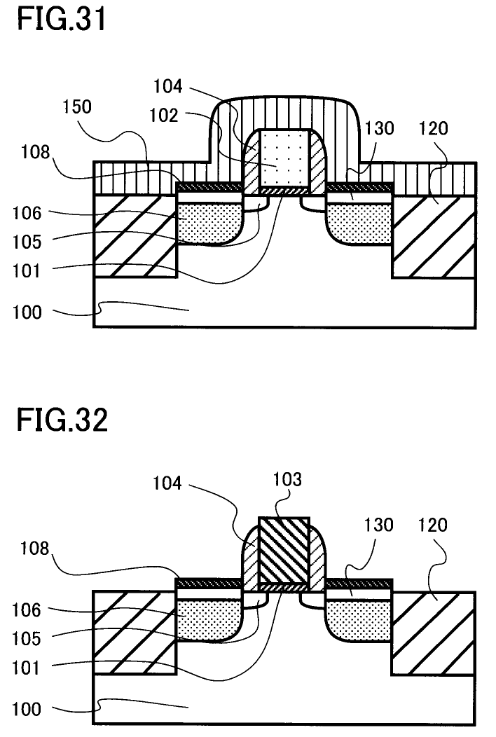

As shown in FIG. 30, after having formed SiGe layers 106 by selective epitaxial growth, consecutively form Si layer 130 and B-doped p⁺-type impurity regions 108 by selective epitaxial growth. Then, as shown in FIG. 31, perform sputtering of a Ni film 150 of about 10 nm thick; thereafter, perform annealing at 400° C. for 90 seconds and selective strip using a chemical to thereby cause Ni film 150 and polysilicon gate electrode 102 to completely react together to a level corresponding to the interface of gate insulator film 101, thereby forming a gate silicide 103 as shown in FIG. 32. At this time, portions of Ni film 150 overlying B-doped p⁺-type impurity regions 108 hardly react with these regions 108 due to the Ni barrierability thereof. Thus no NiSi layer is formed on the impurity regions 108; in addition, Si layer 130 beneath regions 108 is never silicided.

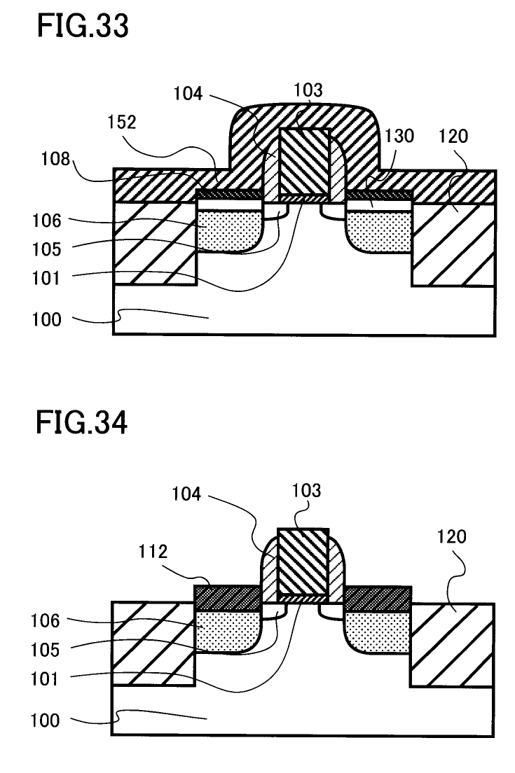

Next, as shown in FIG. 33, after having sputtered a Pt film 152 of about 10 nm thick, perform silicidation by annealing at about 350° C. and then apply thereto selective strip using a chemical, thereby to form a pFET with the patterned PtSi layer 112 as its S/D electrodes as shown in FIG. 34. In this case the p⁺-type impurity regions 108 do not become the diffusion barrier for Pt atoms, so these regions 108 and Si layer 130 are silicided to become PtSi layer 112.

The second exemplary semiconductor device fabrication method shown in FIGS. 30-34 is more excellent than the first exemplary method of FIGS. 25-29 in manufacturability of the intended device structure with its gate silicide and S/D silicide being different in material from each other because of the fact that the former method is arranged to fabricate SiGe layer 106 and p⁺-type impurity regions 108 consecutively in the same process. Thus it is possible to further readily achieve the reduction of parasitic resistance at pFET S/D regions and reduction of threshold voltages of pFET and nFET.

In this embodiment the silicide material for S/D electrodes is not exclusively limited to PtSi and may alternatively be replaced by other similar silicides, such as for example Pd₂Si or else, in view of the optimization of the FET performance.

### Fifth Embodiment

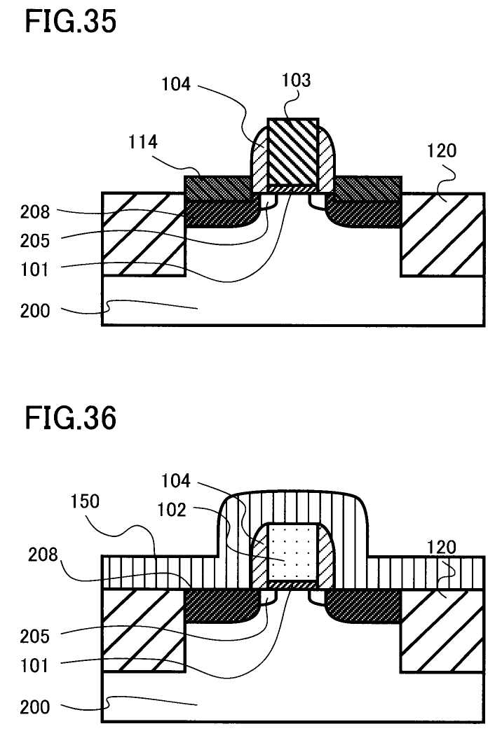

A semiconductor device having a MISFET to be formed by a fabrication method in accordance with another further embodiment of the invention is shown in FIG. 35 in cross-section. This device is similar in structure to that of FIG. 15 with its S/D electrodes being made of the silicide of a rare metal element erbium (Er), i.e., ErSi_{1.7} layer 114.

This nFET is arranged to use as its S/D electrodes the ErSi_{1.7} layer which is lower in electrical resistance than NiSi and thus offers an ability to further reduce the parasitic resistance in addition to the functions and effects of the nFET shown in FIG. 15. Thus it becomes possible to further enhance the FET drivability. Additionally, the work function of ErSi_{1.7} layer is closer than NiSi to the energy of the conduction band of Si so that the silicide/substrate Schottky barrier becomes lower than that of NiSi. From this point also, the interface resistance is reduced, resulting in a likewise decrease in parasitic resistance, thereby to enable achievement of higher drivability. Further, as the rare metal element's silicide interface becomes flat in the level of atoms, the junction leakage reduction effect is enhanced to lower power consumption.

A fabrication method of the semiconductor device of FIG. 35 will be described with reference to FIGS. 36 to 39 below. Note that this method is similar to that shown in FIGS. 16-20 in regard to the process up to the forming of n⁺-type impurity regions (second semiconductor regions) 208 by ion implantation of As and C impurities, so its explanation will be eliminated herein.

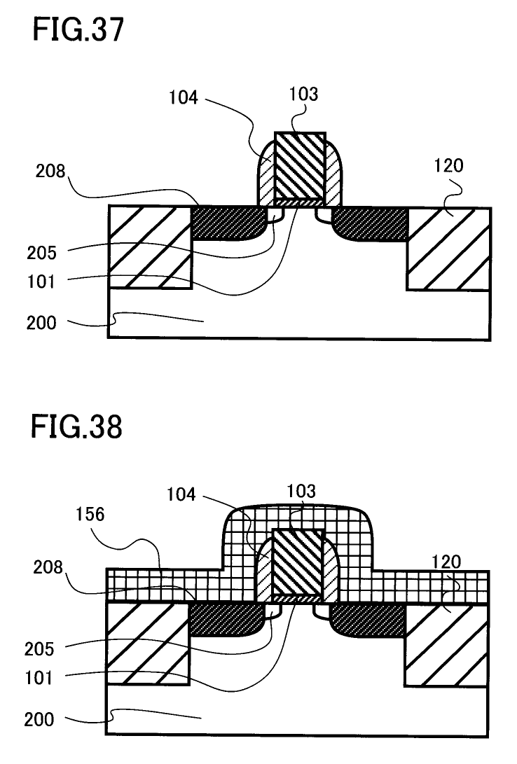

As shown in FIG. 36, after having performed activation annealing (spike anneal) of n⁺-type impurity regions 208 at a temperature of about 1050° C., form by sputtering a Ni film 150 with a thickness of about 10 nm. Thereafter, perform annealing at 400° C. for 90 seconds and selective strip using a chemical solution to cause Ni film 150 and Si layer 130 to react together for silicidation as shown in FIG. 37. Simultaneously, let polysilicon gate electrode 102 completely react until the interface of gate insulator film 101, thereby forming a gate silicide 103. At this time, those portions of Ni film overlying the n⁺-type impurity regions 208 hardly react with these regions 208 due to the Ni barrierability thereof. Thus no NiSi layer is formed on the impurity regions 108.

Next, as shown in FIG. 38, after having performed sputtering of an Er film 156 that is about 10 nm thick, perform silicidation by annealing at about 350° C. and selective strip using a chemical, thereby to form an nFET with its S/D electrodes made of ErSi_{1.7} layer 114 as shown in FIG. 39. At this time the n⁺-impurity regions 208 do not become the barrier against diffusion of Er atoms, so the regions 208 are silicidized.

In the prior art, in order to make the gate silicide and S/D electrode silicide different in material from each other, it has been needed in such silicidation to add very complicated processes for masking those regions that are not desired to be silicided.

Using the semiconductor device fabrication method stated above makes it easier to make the gate silicide and the S/D electrode silicide different in material. This makes it possible to facilitate the reduction of the parasitic resistance of S/D regions while lowering the threshold voltage of pFET and nFET.

The silicide material of S/D electrodes in this embodiment should not exclusively be limited to ErSi_{1.7} and may alternatively be other rare metal element-based material, such as yttrium (Y), ytterbium (Yb) or else.

### Sixth Embodiment

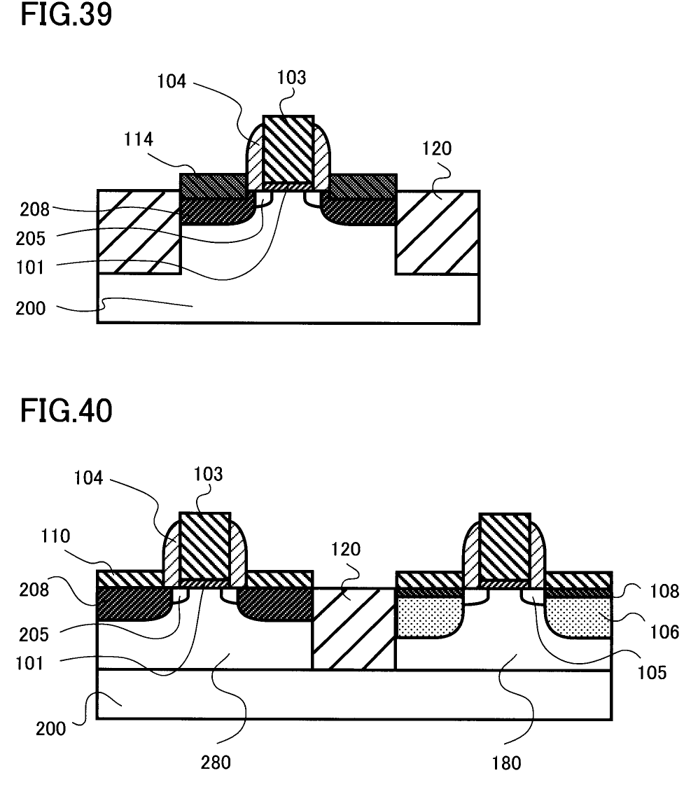

A sectional structure of a semiconductor device having MISFETs in accordance with a further embodiment of the invention is shown in FIG. 40. This embodiment device is characterized in that the pFET shown in FIG. 14 and NFET of FIG. 15 are formed together on a p-type Si substrate 200 to provide a complementary metal insulator semiconductor (CMIS) device structure—here, complementary metal oxide semiconductor (CMOS) device.

This CMOS device offers the functionalities and advantages of the first and third embodiments stated supra. Accordingly, the both pFET and nFET are with low interface resistance, high drivability owing to gate depletion suppressibility, and low junction leakage due to Ni diffusion reducibility. Thus, use of this embodiment makes it possible to achieve high-speed CMOS device of low power consumption.

An explanation will next be given of a fabrication method of the CMOS device while referring to FIGS. 41 to 50.

First, as shown in FIG. 41, a p-type Si substrate 200 is prepared, which has a (100) plane of surface orientation with boron (B) being doped to a concentration of about 10¹⁵ atoms/cm³. Then, form an STI element isolation region 120 comprised of a silicon oxide film. Thereafter, form by ion implantation an n-type semiconductor region (third semiconductor region for use as an n-type well) 180 and a p-type semiconductor region (fifth semiconductor region as a p-type well) 280. Then, form a gate insulator film 101 to a thickness of about 1 nm in EOT, followed by LPCVD deposition of a polysilicon film to a thickness of about 100 to 150 nm, which will eventually become gate electrodes 102.

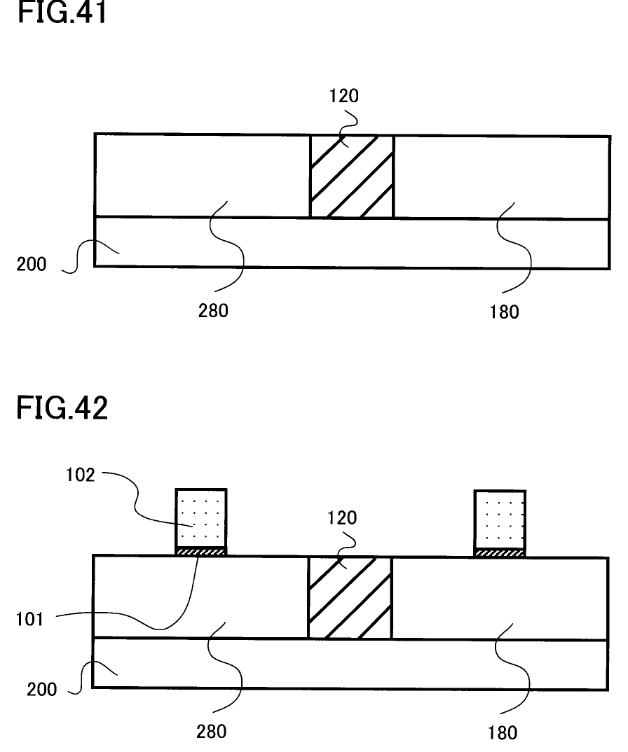

Next, as shown in FIG. 42, selectively etch for patterning the gate insulator film 101 and gate electrodes 102 by known lithography and RIE techniques in a way such that resultant gate length is about 30 nm. Post-oxidation may be performed, if necessary.

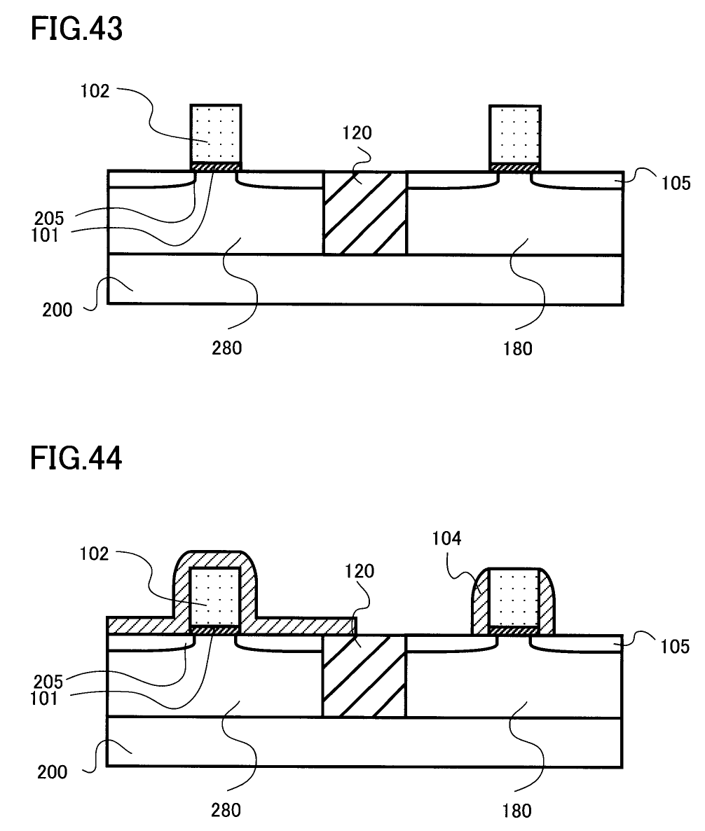

Next as shown in FIG. 43, form by ion implantation using different resist masks one at a time p-type extension diffusion layers 105 with B being doped thereinto to a concentration of about 10²⁰ atoms/cm³ in the n-type well region 180 and n-type extension diffusions 205 doped with As to a concentration of about 10²⁰ atoms/cm³ in the p-type well region 280. Then, apply thereto activation annealing (spike annealing) at a temperature of about 1050° C.

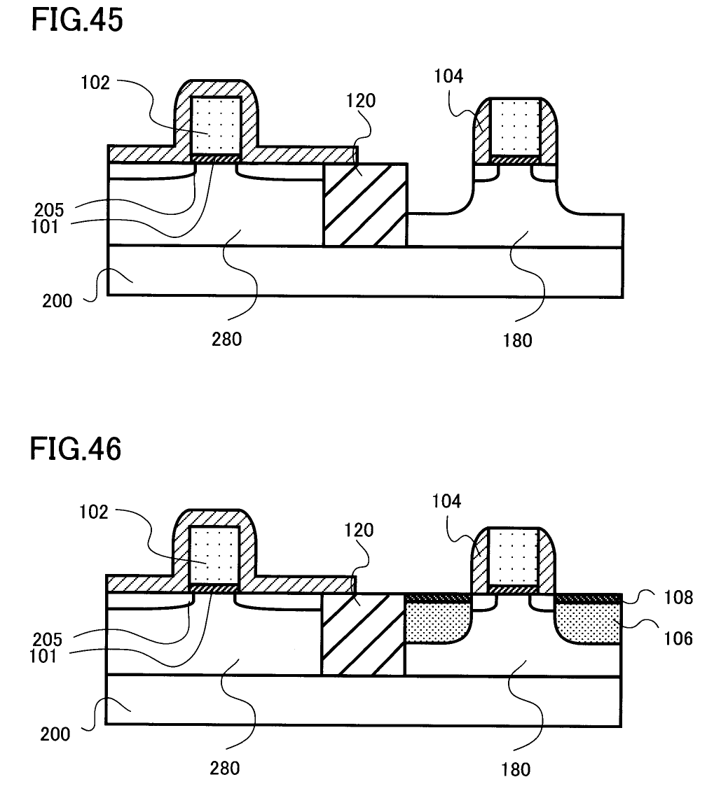

Next as shown in FIG. 44, after having deposited a SiN film by LPCVD to a thickness of about 8 nm, perform etch-back by RIE techniques while letting the p-well region 280 be covered with a resist mask (not shown) to thereby form gate sidewall insulator film 104 in the n-well region 180. Subsequently, as shown in FIG. 45, with gate electrode is 102 and sidewall insulator film 104 being as a mask, etch and recess the p-type extension diffusion layers 105 and Si substrate 100 to a depth of about 30 nm.

After having removed the resist mask, perform selective epitaxial growth of a SiGe film 106 and a p⁺-type impurity regions (fourth semiconductor regions) 108 with respect to the crystal layer on the substrate side in the etch-recessed regions, thereby to fill the etch-recessed regions as shown in FIG. 46.

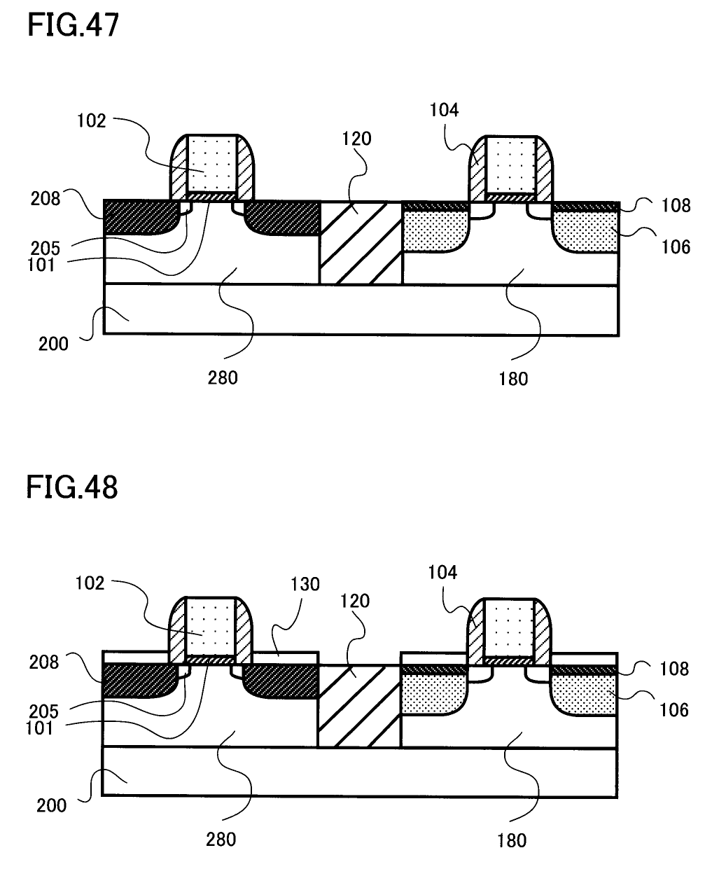

Next as shown in FIG. 47, while covering the n-well region 180 with a resist mask (not shown), etch back by RIE the SiN film on p-well region 280 to form a gate sidewall insulating film 104 on p-well 280. Subsequently, introduce As and C impurities by ion implantation into p-well 280 on Si substrate 200 to thereby form an n⁺-type impurity regions (sixth semiconductor regions) 208 of about 1.5 nm thick. Then, perform activation annealing, called the spike anneal. Thereafter, as shown in FIG. 48, form a patterned Si layer 130 on p-well 108 and n-well 208 by selective epitaxial growth techniques.

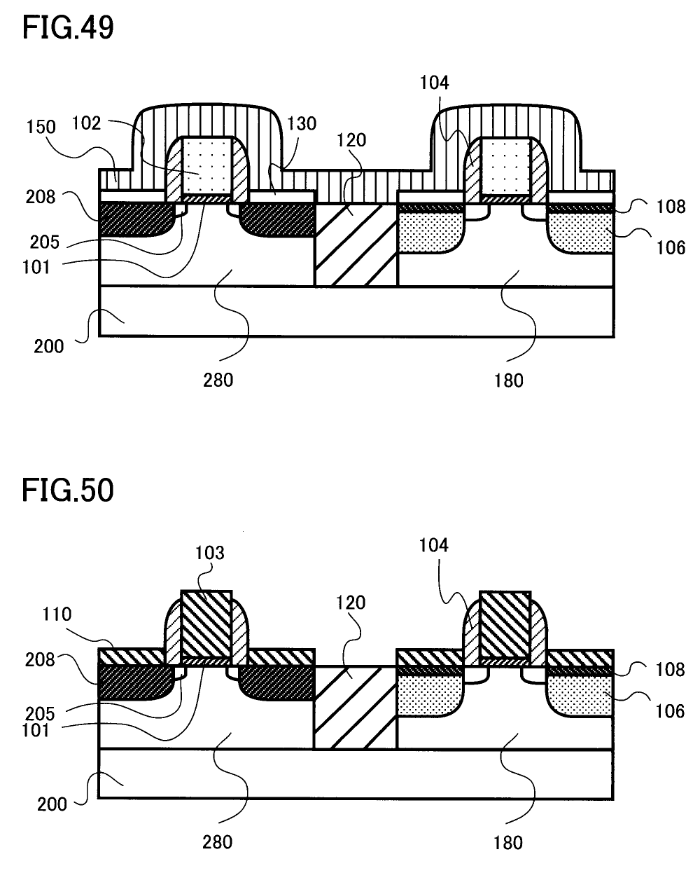

Then, as shown in FIG. 49, after having sputtered Ni film 150 of about 10 nm thick, perform annealing at 400° C. for 90 seconds and selective strip using a chemical to cause Ni film 150 and Si layer 130 to react together for silicidation as shown in FIG. 50. Simultaneously, let polysilicon gate electrodes 102 completely react down to the interface of gate insulator film 101, thereby forming gate silicides 103.

With this embodiment fabrication method, it becomes possible to manufacture the high-speed CMOS device with low power consumption while reducing complexity.

### Seventh Embodiment

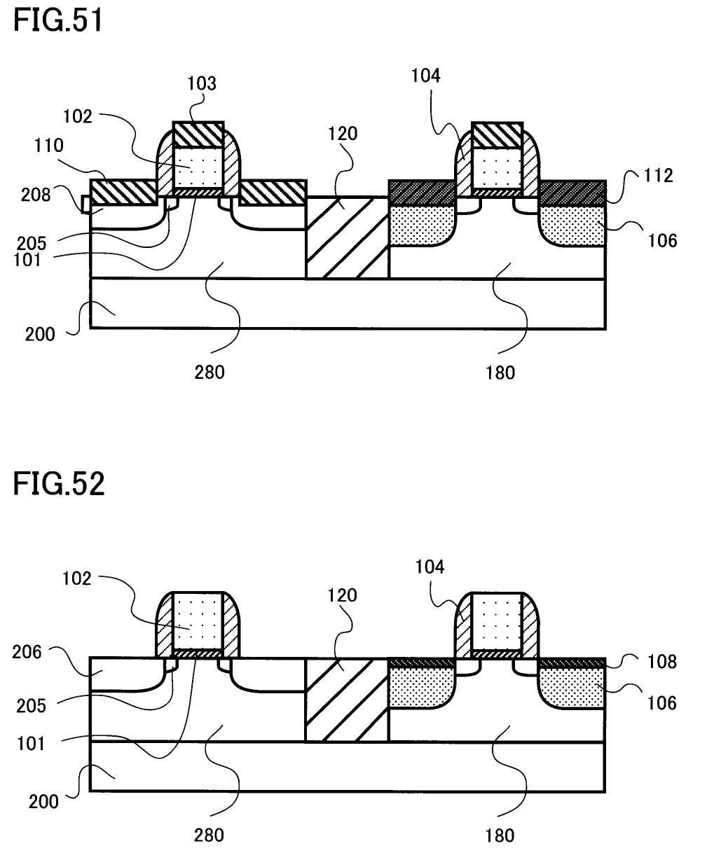

Turning to FIG. 51, a semiconductor device structure having MISFETs to be formed by a fabrication is method in accordance with another further embodiment of the invention is shown in cross-section. A feature of this device lies in that a pair of pFET and nFET is formed on p-type Si substrate 200 to provide CMOS device structure, wherein the pFET is similar to that shown in FIG. 1 with PtSi source/drain (S/D) electrodes being added thereto whereas the nFET has prior known NiSi gate electrode and S/D electrodes.

The pFET of the device shown in FIG. 51 offers the advantages of the FIG. 1 device plus the functions and effects attainable by applying PtSi to its S/D electrodes. Accordingly, regarding pFET, high drivability owing to reduced interface resistance and channel distortion and low junction leakage due to planarization of PtSi interface are achieved. Thus, with this embodiment, it is possible to realize the intended high-speed CMOS device that is low in power consumption.

A fabrication method of the CMOS device shown in FIG. 51 will next be described with reference to FIGS. 52-56. This method is similar to that of the sixth embodiment in the process up to the selective epitaxial growth of SiGe layers 106 and 1.5 nm thick p⁺-type impurity regions 108 in n-type well region 180 in the way as shown in FIGS. 41-46, so the explanation thereof will be omitted here.

As shown in FIG. 52, after having formed by selective epitaxial growth the SiGe layers 106 and 1.5 nm thick p⁺-type impurity regions 108 in n-well 180, etch back by RIE those portions of SiN film on p-well 280 while letting n-well 180 be coated with a resist mask (not shown), thereby to form gate sidewall insulators 104 on or above p-well 280. Continuously, implant As impurity ions into p-well 280 to form n⁺-type diffusion regions 206 with As doped to a concentration of about 3×10²⁰ atoms/cm³. Then, apply activation annealing, i.e., spike anneal.

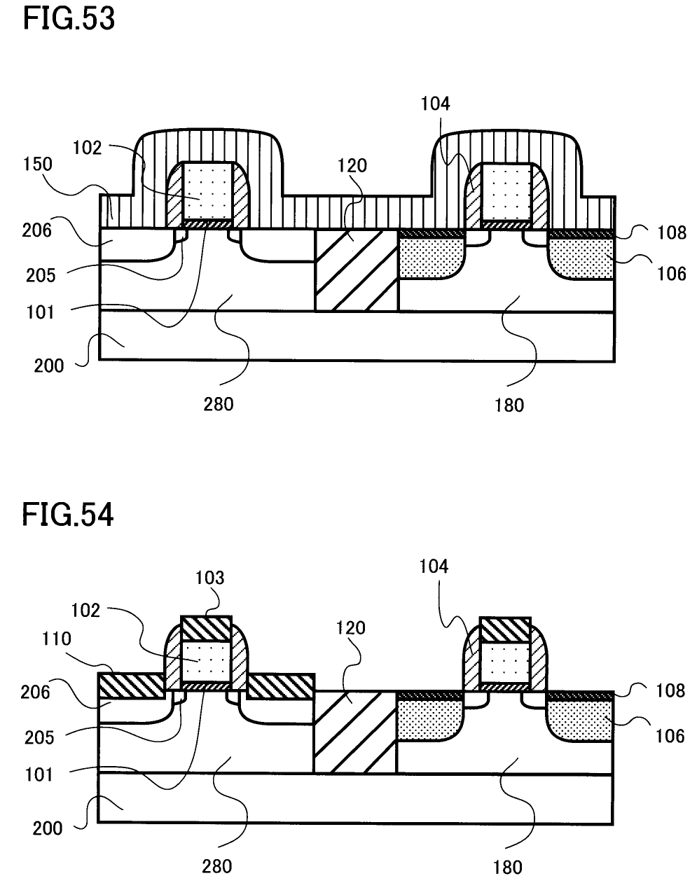

Next, as shown in FIG. 53, form by sputtering a Ni film 150 of about 10 nm thick. Then, perform annealing at 400° C. for 30 seconds and selective removal using a chemical to force Ni film 150 and n-type diffusions 206 in p-well 280 and polysilicon gate electrode 102 to react to thereby form NiSi S/D electrodes 110 and gate silicide 103 as shown in FIG. 54. At this time, those portions of Ni film on p⁺-type B impurity regions 108 hardly react with these regions 108 due to the Ni barrier functionality thereof. Thus, no NiSi layer is formed on p⁺-type regions 108.

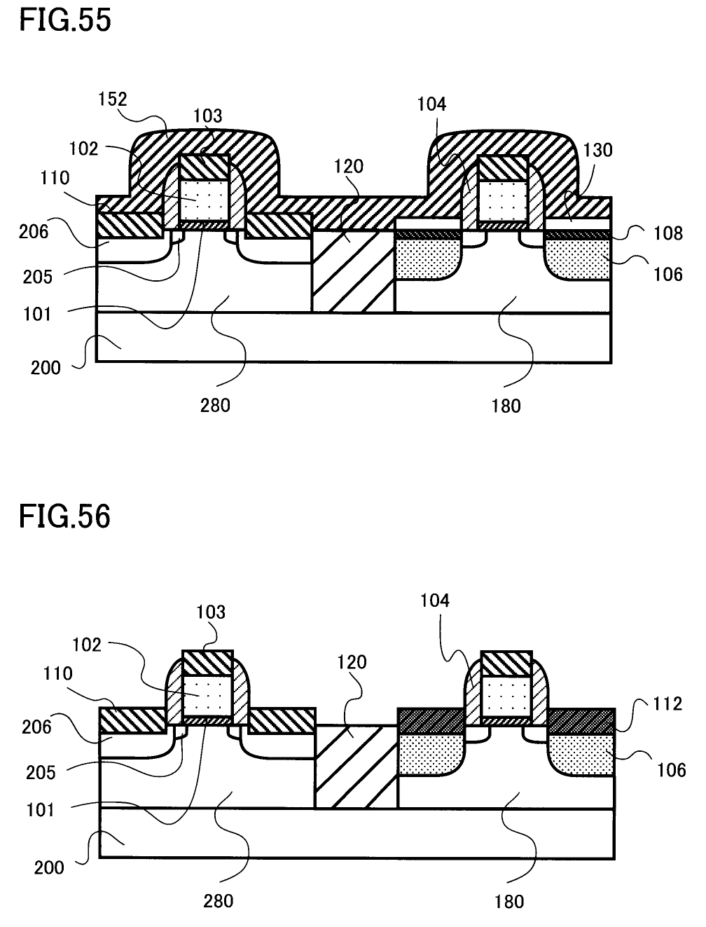

Next as shown in FIG. 55, selectively form an epitaxial grown Si layer 130 on p⁺-type impurity regions 108. Then, after having sputtered a Pt film 152 of about 10 nm thick, perform silicidation by annealing at about 350° C. and selective strip using a chemical to thereby form pFET with its S/D electrodes made of PtSi layer 112 as shown in FIG. 56.

With this embodiment method, it is possible to manufacture the intended high-speed CMOS device with low power consumption.

### Eighth Embodiment

A complementary MISFET (CMISFET) device structure in accordance with another further embodiment of the invention is illustrated in FIG. 57 in cross-section. A feature of this embodiment device is that the pFET of the second embodiment shown in FIG. 14 and the nFET of fifth embodiment of FIG. 35 are formed on a p-type Si substrate 200 to provide a CMOS structure.

This CMOSFET device has the functionalities and advantages of the second and fifth embodiments stated supra. Accordingly, the both pFET and nFET are capable of offering high drivability owing to reduced interface resistance and gate depletion suppression. In addition, the pFET has high drivability owing to channel distortion and offers low junction leakage due to Ni diffusion suppression; the nFET attains high drivability owing to lowered electrode resistance due to the use of ErSi_{1.7} layer and low junction leakage due to silicide interface planarization. Thus, using this embodiment makes it possible to achieve high-speed CMOS device with low power consumption.

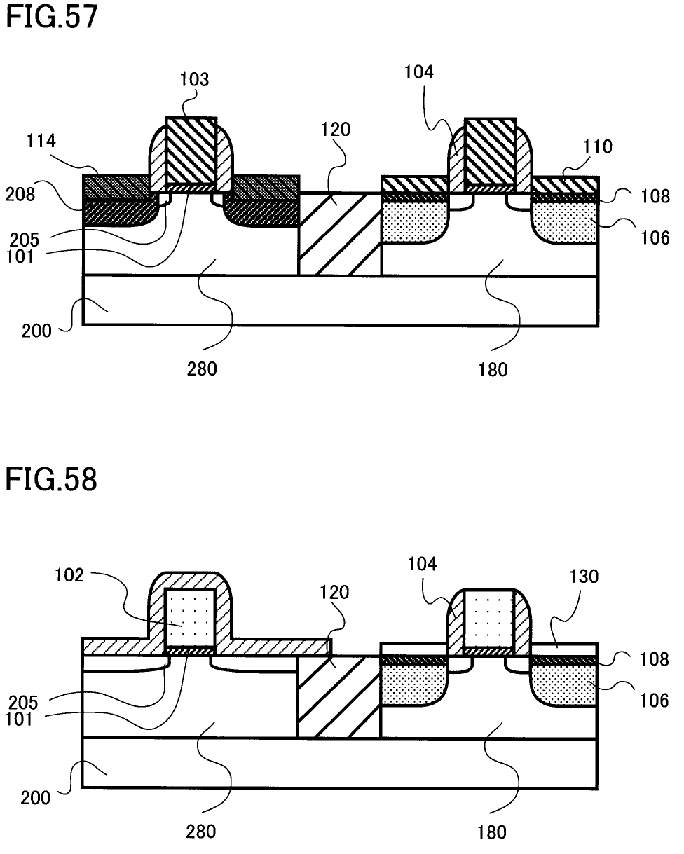

A fabrication method of the FIG. 57 device will next be discussed with reference to FIGS. 58-63. This method is similar to that of the sixth embodiment of FIGS. 41-46 in the process up to the selective epitaxial growth of SiGe layers 106 and 1.5 nm-thick p⁺-type impurity regions 108 in n-type well 180, so an explanation thereof will be eliminated.

After completion of selective epitaxial growth of p⁺-type impurity regions (fourth semiconductor regions) 108, continuously perform selective epitaxial growth to form Si layer 130 on p⁺-type regions 108 as shown in FIG. 58.

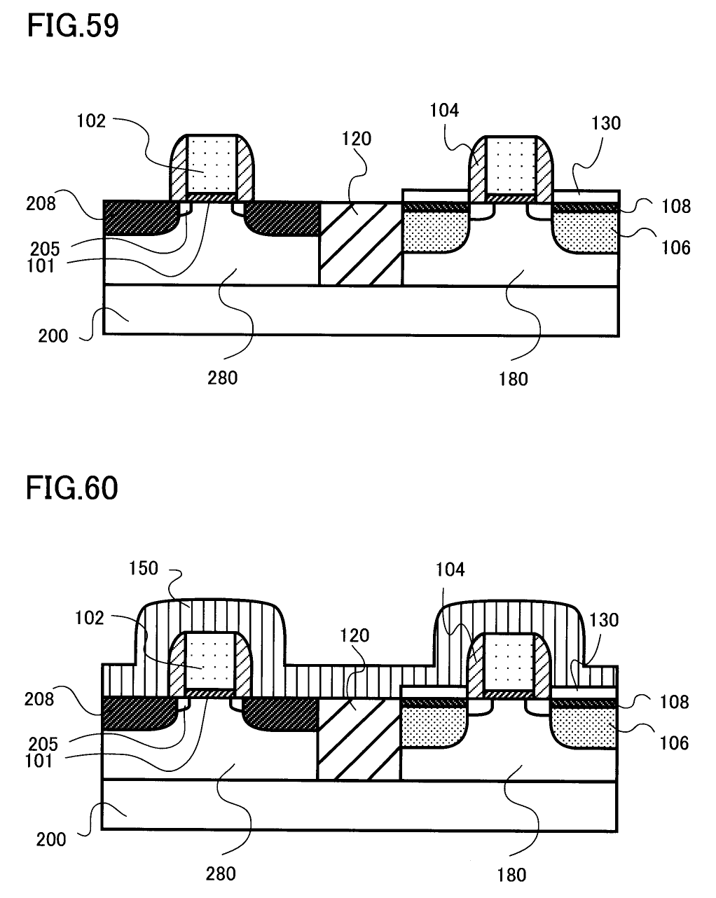

Next, as shown in FIG. 59, certain portions of SiN film on p-well 280 are applied etch-back by RIE while letting n-well 180 be covered with a resist mask (not shown), thereby forming gate sidewall insulators 104 on p-well 280. Subsequently, introduce As and C impurities by ion implantation into p-well 280 to form n⁺-type diffusion regions 208 of about 1.5 nm thick, followed by execution of activation annealing (spike annealing).

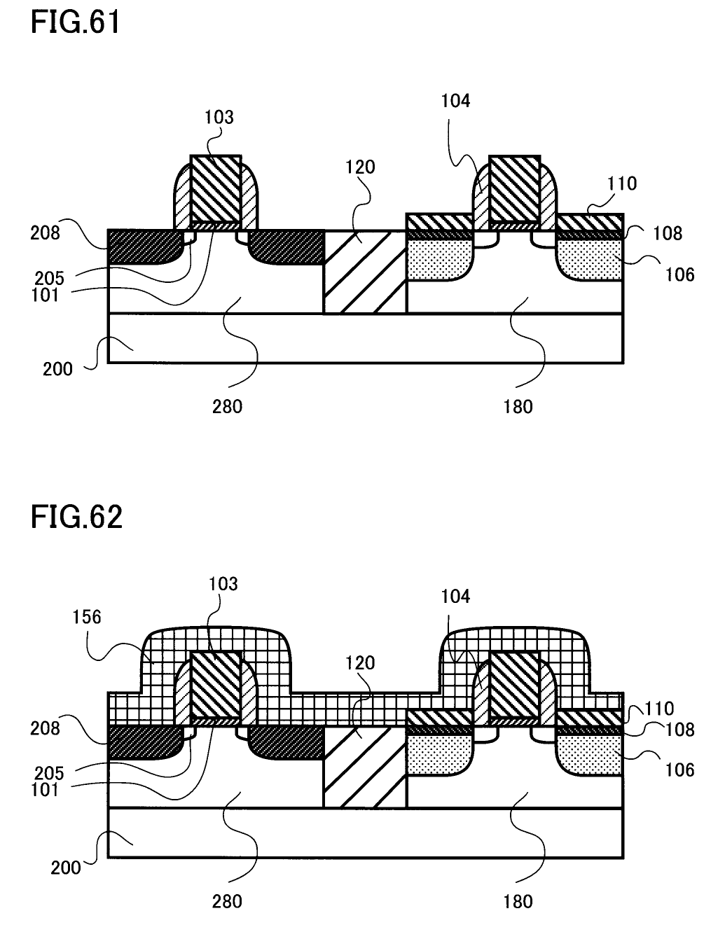

Next as shown in FIG. 60, after having sputtered 10 nm-thick Ni film 150, perform annealing at 400° C. for 90 seconds and selective strip using a chemical to allow Ni film 150 and Si layer 130 of n-well 180 to react for silicidation as shown in FIG. 61. Simultaneously, let polysilicon gate electrodes 102 completely react down to the interface of gate insulator film 101, thereby to form gate silicides 103. At this time, portions of Ni film 150 on the n⁺-type impurity regions (sixth semiconductor regions) 208 hardly react with these regions 208 due to the Ni barrierability thereof. This ensures that no NiSi layer is is formed on p⁺-type regions 208.

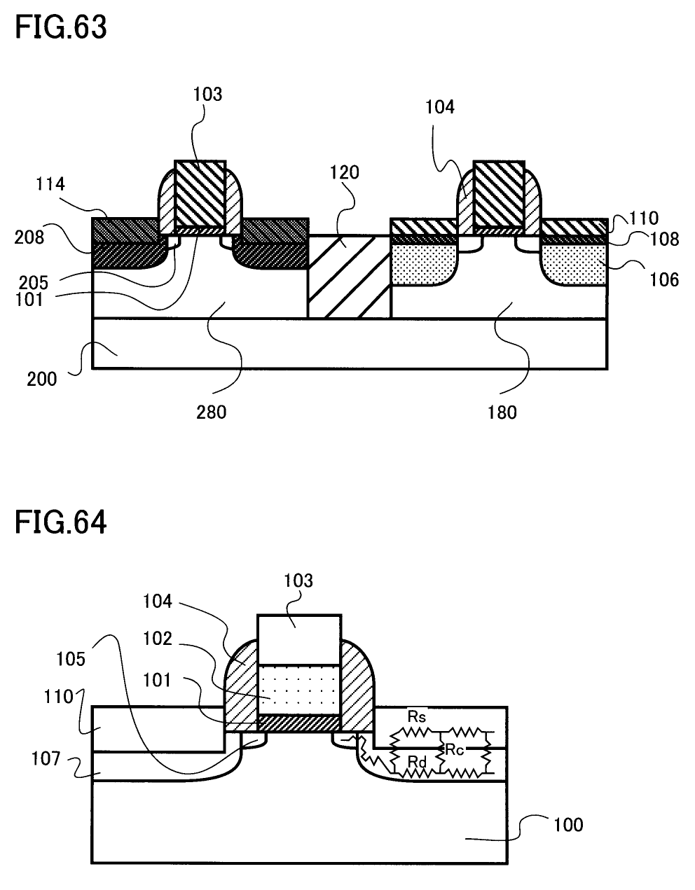

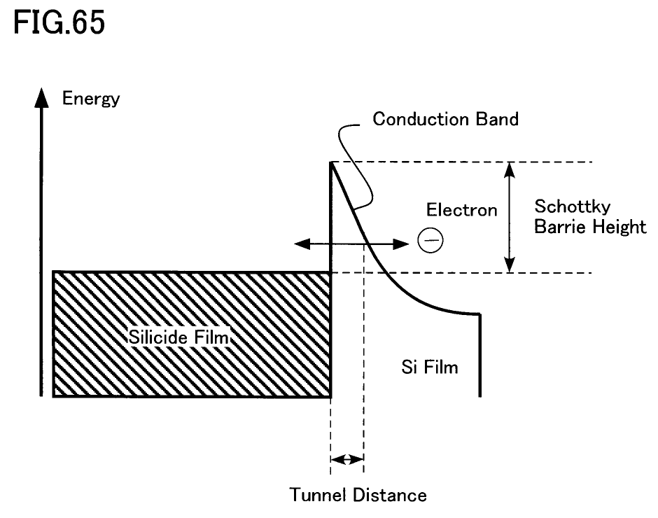

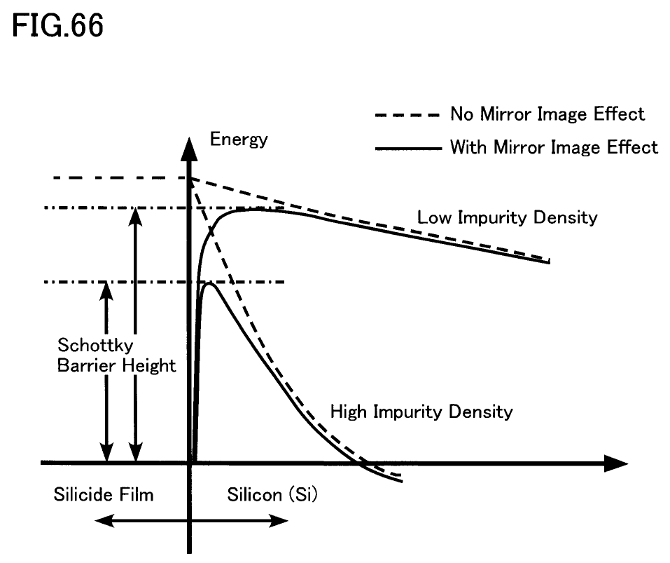

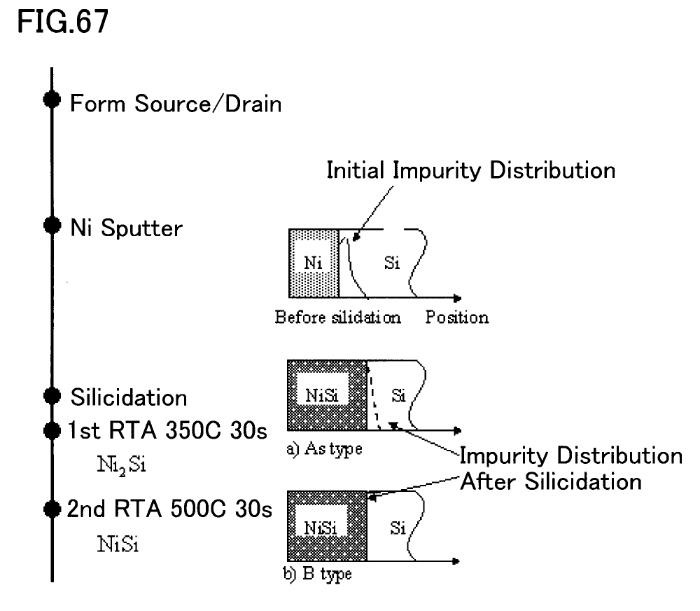

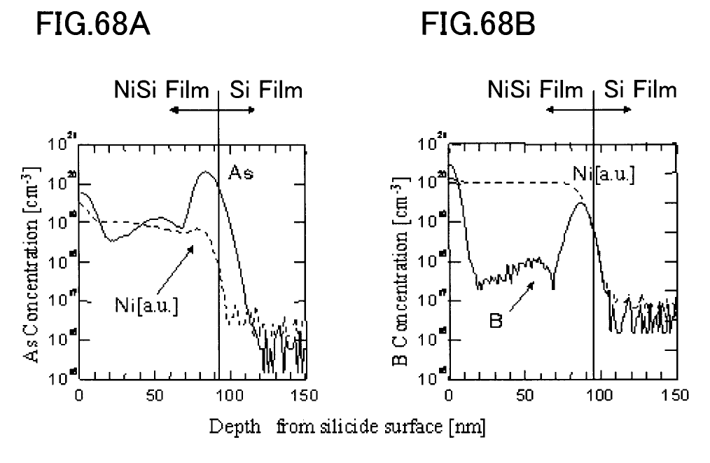

Next as shown in FIG. 62, after having sputtered an Er film 156 to a thickness of about 10 nm, perform silicidation by annealing at about 350° C. and selective strip using a chemical to thereby form nFET with its S/D electrodes made of ErSi_{1.7} layer 114 as shown in FIG. 63. At this time, the n⁺-type impurity regions 208 do not become the barrier against diffusion of Er atoms, so regions 208 are silicided.

With this fabrication method, it is possible to manufacture the high-speed CMOS device of low power consumption.

Although the invention has been described with reference to specific embodiments, the description is illustrative of the invention and is not to be construed as limiting the invention. While in the embodiments the semiconductor substrate is made of silicon (Si), this material is not restrictive of this invention and may be replaced by other similar suitable materials including, but not limited to, silicon germanium (SiGe), germanium (Ge), silicon carbide (SiC), gallium arsenide (GaAs) and aluminum nitride (AlN).

Additionally, the surface orientation of the substrate material should not exclusively limited to the (100) plane and is alternatively settable to a (110) or (111) plane on a case-by-case basis. The principal concepts of this invention are applicable to any available MISFET and CMISFET devices including three-dimensional (3D) structures, such as a finned structure and double-gate structure. The principles involved are susceptible for use in numerous other embodiments, modifications and alterations which will be apparent to persons skilled in the art to which the invention pertains. The invention is, therefore, to be limited only as indicated by the scope of the appended claims.

What is claimed is:

1. A method of fabricating a semiconductor device, comprising:
forming a gate electrode above a first semiconductor region of first type conductivity with a gate insulation film being interposed therebetween;
forming a sidewall dielectric film on both side faces of said gate electrode;
forming in or on said first semiconductor region a second semiconductor region of second type conductivity having an impurity concentration of more than or equal to 10²¹ atoms per cubic centimeter (atoms/cm³) and yet less than or equal to 10²² atoms/cm³;
forming a silicon (Si) layer on said second semiconductor region; and
silicidizing said silicon layer by letting this layer react with a metal containing nickel (Ni) therein.

2. The method according to claim 1, wherein said gate electrode is made of silicon and wherein when silicidizing said silicon layer by reaction with a nickel-containing metal, said gate electrode is caused to react with the metal to a level corresponding to an interface of the gate insulation film to thereby perform silicidation.

3. The method according to claim 1, wherein said second semiconductor region has a thickness of more than or equal to 0.55 nanometers (nm) and less than or equal to 2 nm.

4. The method according to claim 1, wherein the impurity is boron (B).

5. The method according to claim 1, wherein the impurity is a mixture of arsenic (As) and carbon (C).

6. A method of fabricating a semiconductor device, comprising:
forming a gate electrode above a first semiconductor region of first type conductivity with a gate insulation film being interposed therebetween;
forming a sidewall dielectric film on both side faces of said gate electrode;
etching said first semiconductor region with said sidewall dielectric film being as a mask therefor;
forming a layer of SiₓGe₁₋ₓ (0<x<1) in an etched region of said first semiconductor region;
forming on the layer of SiₓGe₁₋ₓ a second semiconductor region of second type conductivity having an impurity concentration of more than or equal to 10²¹ atoms/cm³ and yet less than or equal to 10²² atoms/cm³;
forming a silicon (Si) layer on said second semiconductor region; and
silicidizing said silicon layer by causing this layer to react with a nickel (Ni)-containing metal.

7. The method according to claim 6, wherein said gate electrode is made of silicon and wherein when silicidizing said silicon layer by reaction with a nickel-containing metal, said gate electrode is caused to react with the metal to a level corresponding to an interface of the gate insulation film to thereby perform silicidation.

8. The method according to claim 6, wherein said second semiconductor region has a thickness of more than or equal to 0.55 nm and less than or equal to 2 nm.

9. The method according to claim 6, wherein the impurity is boron (B).

10. A method of fabricating a semiconductor device, comprising:
forming a gate electrode above a first semiconductor region of first type conductivity with a gate insulation film being interposed therebetween;
forming a sidewall dielectric film on both side faces of said gate electrode;
etching said first semiconductor region with said sidewall dielectric film being as a mask therefor;
forming a layer of SiₓGe₁₋ₓ (0<x<1) in an etched region of said first semiconductor region;
forming on the layer of SiₓGe₁₋ₓ a second semiconductor region of second type conductivity having an impurity concentration of more than or equal to 10²¹ atoms/cm³ and yet less than or equal to 10²² atoms/cm³;
silicidizing said gate electrode by letting this electrode react with a nickel (Ni)-containing metal to a level corresponding to an interface of said sidewall dielectric film;
forming a silicon (Si) layer on said second semiconductor region; and
silicidizing said silicon layer through reaction with a metal excluding containment of nickel therein.

11. A method of fabricating a semiconductor device, comprising:
forming a gate electrode made of silicon (Si) above a first semiconductor region of first type conductivity with a gate insulation film being interposed therebetween;
forming a sidewall dielectric film on both side faces of said gate electrode;
etching said first semiconductor region with said sidewall dielectric film being as a mask to thereby define an etched region;
forming a layer of SiₓGe₁₋ₓ (0<x<1) in the etched region of said first semiconductor region;
forming on the SiₓGe₁₋ₓ layer a layer of silicon;
forming on the silicon layer a second semiconductor region of second type conductivity having an impurity concentration of more than or equal to 10²¹ atoms/cm³ and yet less than or equal to 10²² atoms/cm³;
silicidizing said gate electrode by letting this electrode react with a nickel (Ni)-containing metal to a level corresponding to an interface of said sidewall dielectric film; and
silicidizing said second semiconductor region and said silicon layer by reaction with a metal excluding containment of nickel therein.

12. A semiconductor device comprising:
a first semiconductor region of first type conductivity with a channel region being formed therein;
a gate electrode overlying the channel region with a gate insulator film being sandwiched therebetween;
a layer of SiₓGe₁₋ₓ (0<x<1) on both sides of the channel region;
a second semiconductor region of second type conductivity as formed on or above the SiₓGe₁₋ₓ layer to have an impurity concentration of more than or equal to 10²¹ atoms/cm³ and yet less than or equal to 10²² atoms/cm³; and
a silicide layer containing nickel (Ni) as formed above said second semiconductor region.

13. The device according to claim 12, wherein said second semiconductor region has a thickness of more than or equal to 0.55 nm and less than or equal to 2 nm.

14. The device according to claim 12, wherein the impurity is boron (B).

15. The device according to claim 12, wherein said silicide layer contains platinum (Pt).

16. The device according to claim 12, wherein said gate electrode is a monolayer of silicide.

17. A semiconductor device comprising:
a semiconductive substrate;
a pair of field effect transistors (FETs) having opposite conductivity types on said substrate, one of the FETs being of a p-type FET and a remaining one of said FETs being of an n-type FET;
said p-type FET including a third semiconductor region of n-type conductivity with a first channel region being formed therein, a gate electrode overlying said first channel region with a gate insulator film being interposed therebetween, a layer of SiₓGe₁₋ₓ (0<x<1) on both sides of said first channel region, a fourth semiconductor region of p-type conductivity as formed on the SiₓGe₁₋ₓ layer to have an impurity concentration of more than or equal to 10²¹ atoms/cm³ and yet less than or equal to 10²² atoms/cm³, and a first silicide layer containing therein nickel (Ni) as formed above said fourth semiconductor region; and
said n-type FET including a fifth semiconductor region of p-type conductivity with a second channel region being formed therein, a gate electrode overlying said second channel region with a gate insulator film being interposed therebetween, and a second silicide layer on both sides of said second channel region.

18. The device according to claim 17, wherein said second silicide layer contains nickel (Ni) and is formed on or above a sixth semiconductor region of n-type conductivity with its impurity concentration being more than or equal to 10²¹ atoms/cm³ and less than or equal to 10²² atoms/cm³.

19. The device according to claim 18, wherein said impurity is a mixture of arsenic (As) and carbon (C).

20. The device according to claim 17, wherein said second silicide layer is made of a silicide of any one of erbium (Er), yttrium (Y) and ytterbium (Yb).
